(19) United States
(12) Patent Application Publication
(10) Pub. No.: US 2024/0381720 A1
(43) Pub. Date: Nov. 14, 2024

(54) DISPLAY DEVICE AND METHOD OF MANUFACTURING DISPLAY DEVICE

(71) Applicant: Samsung Display Co., Ltd., Yongin-Si (KR)

(72) Inventors: Hyung Keun PARK, Yongin-si (KR); Jong Hyeon LEE, Yongin-si (KR)

(21) Appl. No.: 18/411,040

(22) Filed: Jan. 12, 2024

(30) Foreign Application Priority Data
May 10, 2023 (KR) 10-2023-0060524

(51) Int. Cl. H10K 59/131; H10K 59/12; H10K 59/122

(52) U.S. Cl. CPC H10K 59/131; H10K 59/1201; H10K 59/122

(57) ABSTRACT

A display device comprises: a pixel-circuit layer comprising a pixel circuit and an auxiliary pixel circuit on a base layer; and a light-emitting-element layer comprising a light emitting element electrically connected to the pixel circuit. The pixel-circuit layer comprises a line part and an electrode part electrically connected to the line part. The light-emitting-element layer comprises an organic layer comprising a first region and a second region. In a plan view, the first region and the second region are spaced apart from each other with the electrode part interposed therebetween. The line part is electrically connected to the auxiliary pixel circuit.

### CROSS-REFERENCE TO RELATED APPLICATION

This application claims priority to and benefits of Korean patent application No. 10-2023-0060524 under 35 U.S.C. § 119, filed on May 10, 2023, in the Korean Intellectual Property Office, the entire contents of which are incorporated herein by reference.

### BACKGROUND

### Technical Field

The disclosure generally relates to a display device and a method of manufacturing a display device.

### Related Art

With the development of information technologies, display devices have become widely used as connection medium for providing information to users. The need for high-resolution devices has particularly increased as the use of display devices has extended to many fields and applications.

A display device may include an array of sub-pixels with each sub-pixel including a light emitting element. Additionally, a display device typically includes a backplane structure that may include a pixel circuit and the like, and multiple lines may be patterned in one area of the backplane structure. In such a display device, it is necessary to distinguish and keep separate electrical signals respectively supplied to the sub-pixels that may be adjacent to each other. For example, a risk that the electrical signals will be mixed may occur due to a leakage current (lateral leakage) between the sub-pixels. Accordingly, there is a need for display devices and display device fabrication processes that reduce the risk of leakage currents.

### SUMMARY

Embodiments disclosed herein may provide display devices or methods of manufacturing a display device that prevent, avoid, or reduce risks of malfunctions such as leakage currents.

Embodiments may also provide a display device and a method of manufacturing a display device, in which high-resolution display performance can be improved.

Embodiments also provide a display device and a method of manufacturing a display device, in which a fabrication process is simplified so that the degree of freedom in a line design can be increased.

In accordance with an aspect of the disclosure, a display device may include a pixel circuit layer and a light-emitting-element layer. The pixel-circuit layer may include a pixel circuit and an auxiliary pixel circuit on a base layer, and the light-emitting-element layer may include a light emitting element electrically connected to the pixel circuit. In an embodiment, the pixel-circuit layer includes a line part and an electrode part electrically connected to the line part, and the light-emitting-element layer includes an organic layer comprising a first region and a second region. In a plan view, the first region and the second region may be spaced apart from each other with the electrode part interposed therebetween, and the line part may be electrically connected to the auxiliary pixel circuit.

The light-emitting-element layer may further comprise a repaired light emitting element electrically separated from the pixel circuit, the repaired light emitting element being electrically connected to the auxiliary pixel circuit. Each of the light emitting element and the repaired light emitting element may comprise an anode electrode, a cathode electrode, and a light emitting part which is electrically connected between the anode electrode and the cathode electrode and comprises an organic material.

The line part may be electrically connected to the repaired light emitting element through a connection area and may not be electrically connected to the light emitting element with a non-connection area interposed therebetween.

The light emitting part may comprise a first light emitting part and a second light emitting part, which are spaced apart from each other. The first region may comprise the first light emitting part, and the second region may comprise the second light emitting part.

The light-emitting-element layer may further comprise a pixel defining layer comprising a first pixel defining layer and a second defining layer, which define an area in which the light emitting part is disposed and are spaced apart from each other. The first region may further comprise the first pixel defining layer, and the second region may further comprise the second pixel defining layer.

Each of the pixel circuit and the auxiliary pixel circuit may comprise a driving transistor, a switching transistor, a compensation transistor, an initialization transistor, an operation control transistor, an emission control transistor, and a storage capacitor. The pixel circuit may further comprise a bypass transistor. The auxiliary pixel circuit may further comprise a capacitance control transistor, a capacitive element initialization transistor, and a compensation transistor. The line part may be electrically connected to an output node between the capacitance control transistor and the capacitive element initialization transistor.

The repaired light emitting element may be electrically connected to the line part through a connection electrode. The connection electrode may be electrically separated from the emission control transistor and the bypass transistor of the pixel circuit.

The light emitting element may be electrically connected to the emission control transistor and the bypass transistor of the pixel circuit through one electrode which is not electrically connected to the line part.

The pixel-circuit layer may further comprise a data line and a power line, which are electrically connected to the pixel circuit. The data line and the power line may be spaced apart from each other in a first direction and extend in a second direction different from the first direction. The electrode part may be between the data line and the power line and may be adjacent to the connection electrode along the first direction.

The pixel-circuit layer may comprise a first interlayer conductive layer, a second interlayer conductive layer on the first interlayer conductive layer, and a third interlayer conductive layer on the second interlayer conductive layer. The line part may be formed by the second interlayer conductive layer, and the electrode part may be formed by the third interlayer conductive layer.

The pixel-circuit layer may comprise a first interlayer conductive layer, a second interlayer conductive layer on the first interlayer conductive layer, a third interlayer conductive layer on the second interlayer conductive layer, and a fourth interlayer conductive layer on the third interlayer conductive layer. The pixel-circuit layer may further comprise a bridge part electrically connecting the line part and the electrode part to each other. The line part may be formed by the second interlayer conductive layer, the bridge part may be formed by the third interlayer conductive layer, and the electrode part may be formed by the fourth interlayer conductive layer.

The first region and the second region may be spaced apart from each other with an organic material removed area interposed therebetween. The pixel-circuit layer may further comprise a via layer directly adjacent to the light-emitting-element layer, and the via layer may not be disposed in the organic material removed area.

In a plan view, the electrode part may not overlap with an area in which the anode electrode and the light emitting part are in contact with each other.

The light emitting element may comprise a plurality of light emitting elements forming sub-pixels which are different from each other and are adjacent to each other along one direction. The line part may be disposed between the adjacent sub-pixels.

In accordance with another aspect of the disclosure, there is provided a display device comprising: a sub-pixel and a repaired sub-pixel, formed on a base layer, the sub-pixel and the repaired sub-pixel, each comprising a light emitting element; and a line part disposed on the base layer and an electrode part on the line part, wherein the light emitting element comprises a first electrode, a second electrode, and a light emitting layer which is electrically connected between the first electrode and the second electrode and comprises an organic material, wherein the sub-pixel comprises a pixel circuit, wherein the repaired sub-pixel comprises a repair pixel circuit, wherein the line part electrically connects the repair pixel circuit to the light emitting element comprised in the repaired sub-pixel, and wherein, in a plan view, the light emitting layer comprises a first light emitting layer and a second light emitting layer, which are spaced apart from each other, and the electrode part is disposed between the first light emitting layer and the second light emitting layer.

In accordance with still another aspect of the disclosure, there is provided a method of manufacturing a display device, the method comprising: manufacturing a pixel-circuit layer comprising a pixel circuit, a repair pixel circuit, a line part electrically connected to the repair pixel circuit, and an electrode part electrically connected to the line part; disposing a light-emitting-element layer comprising light emitting elements on the pixel-circuit layer; removing at least a portion of an organic layer disposed on the electrode part by applying a pulse input to the line part; inspecting the pixel circuit; and performing a repair process of electrically connecting the repair pixel circuit to at least some of the light emitting elements.

Each of the light emitting elements may comprise an anode electrode, a cathode electrode, and a light emitting part which is electrically connected between the anode electrode and the cathode electrode and comprises an organic material. The removing may comprise removing at least a portion of the light emitting part.

The inspecting may comprise deciding whether the light emitting element normally operates. In the inspecting, the light emitting elements may be electrically connected to the pixel circuit and may not be electrically connected to the repair pixel circuit.

The performing of the repair process may include electrically separating a light emitting element to be repaired, which does not normally operate, from the pixel circuit; and electrically connecting the light emitting element to be repaired to the repair pixel circuit.

The pixel circuit may comprise an emission control transistor and a bypass transistor. The manufacturing of the pixel-circuit layer may comprise forming a connection part having at least a portion overlapping with the line part in a plan view, the connection part being electrically connected to the anode electrode. The performing of the repair process may comprise electrically connecting the connection electrode and the line part to each other.

### BRIEF DESCRIPTION OF THE DRAWINGS

FIG. 1 is a block diagram illustrating a display device in accordance with an embodiment of the disclosure.

FIG. 2 is a schematic sectional view illustrating a display device in accordance with an embodiment of the disclosure.

FIGS. 3 and 4 are schematic sectional views illustrating a stacked structure of a pixel-circuit layer in accordance with an embodiment of the disclosure.

FIG. 5 is a schematic sectional view illustrating a light emitting element in accordance with an embodiment of the disclosure.

FIG. 6 is a schematic block diagram illustrating an electrical connection structure of a light emitting element in accordance with an embodiment of the disclosure.

FIG. 7 illustrates a pixel circuit in accordance with an embodiment of the disclosure.

FIG. 8 illustrates a repair pixel circuit in accordance with an embodiment of the disclosure.

FIG. 9 is a schematic view illustrating a structure in which a light emitting element is electrically connected to a pixel circuit in accordance with an embodiment of the disclosure.

FIG. 10 is a schematic view illustrating a structure in which a light emitting element is electrically connected to a repair pixel circuit in accordance with an embodiment of the disclosure.

FIG. 11 is a view schematically illustrating an organic layer removing process in accordance with an embodiment of the disclosure.

FIGS. 12 and 13 are schematic sectional views illustrating a display device in accordance with an embodiment of the disclosure.

FIG. 14 is a schematic flowchart illustrating a method of manufacturing a display device in accordance with an embodiment of the disclosure.

FIGS. 15 to 30 are schematic views illustrating the method in accordance with the embodiment of the disclosure.

### DETAILED DESCRIPTION

Example embodiments will now be described more fully hereinafter with reference to the accompanying drawings. Embodiments may have forms different from those illustrated in the drawings, and this disclosure should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration and for better understanding. Like reference numerals refer to like elements throughout.

The embodiments described in detail only illustrate particular examples, but various changes and different shapes may be applied. Accordingly, the examples do not limit to certain shapes but apply to all the change and equivalent material and replacement.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to comprise the plural forms as well, unless the context clearly indicates otherwise.

It will be understood that the terms “comprises” and/or “comprising”, when used in this specification, specify the presence of stated features, integers, steps, operations, elements, and/or components but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element. It will be understood that when an element is referred to as being “between” two elements, it can be the only element between the two elements or one or more intervening elements may also be present.

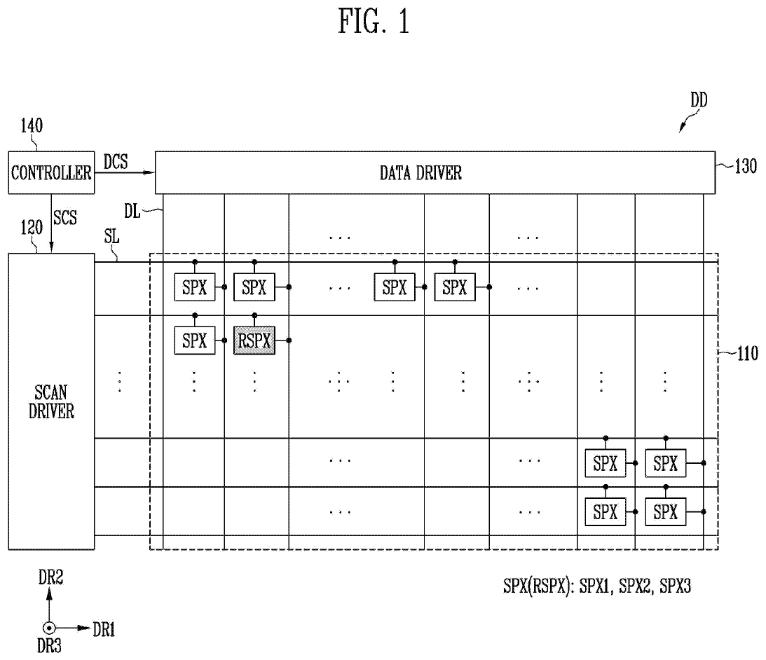

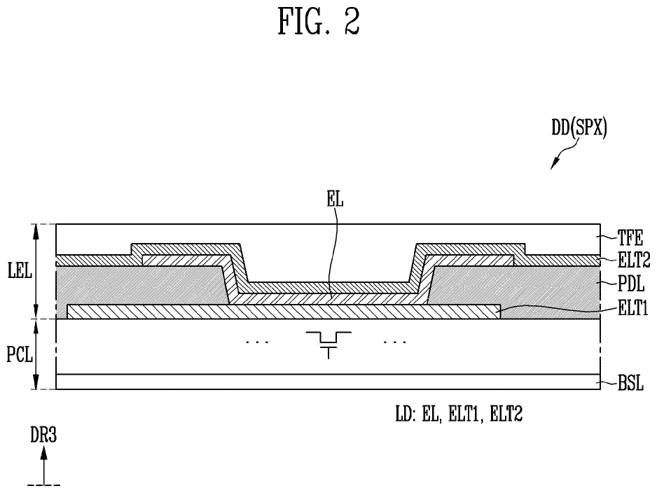

The disclosure generally relates to a display device and a method of manufacturing a display device. FIG. 1 is a block diagram illustrating a display device DD in accordance with an embodiment of the disclosure. The display device DD is configured to emit light and may be an electronic device using a light emitting element LD (see FIG. 2) as a light source. In the illustrated embodiment, the display device DD includes a pixel array 110, a scan driver 120, a data driver 130, and a controller 140.

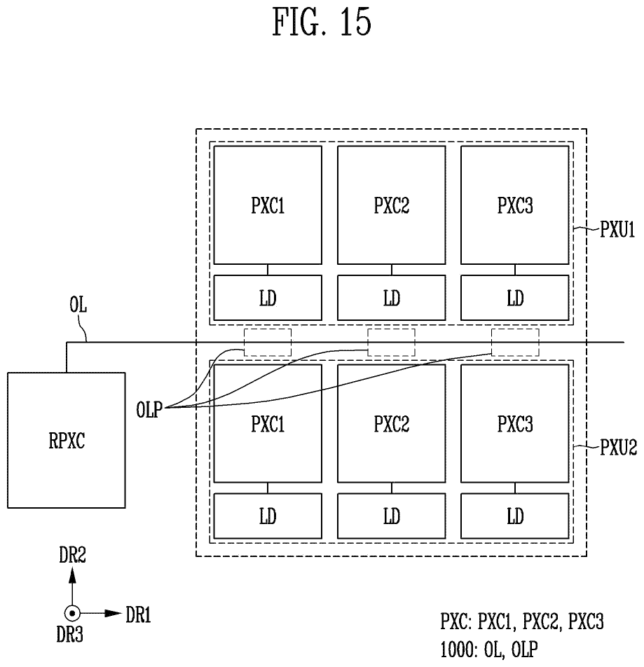

The pixel array 110 may comprise sub-pixels SPX connected to scan lines SL and data lines DL. In some embodiments, one or more of the sub-pixels SPX may form a pixel unit (e.g., a first pixel unit PXU1 and a second pixel unit PXU2 (see FIG. 15)). Each of the sub-pixels SPX may be one of first to third sub-pixels SPX1, SPX2, and SPX3 making up a color pixel. For example, the sub-pixel SPX may comprise a first sub-pixel SPX1 emitting light of a first color (e.g., red), a second sub-pixel SPX2 emitting light of a second color (e.g., green), and a third sub-pixel SPX3 emitting light of a third color (e.g., blue). However, the disclosure is not limited to the above-described example.

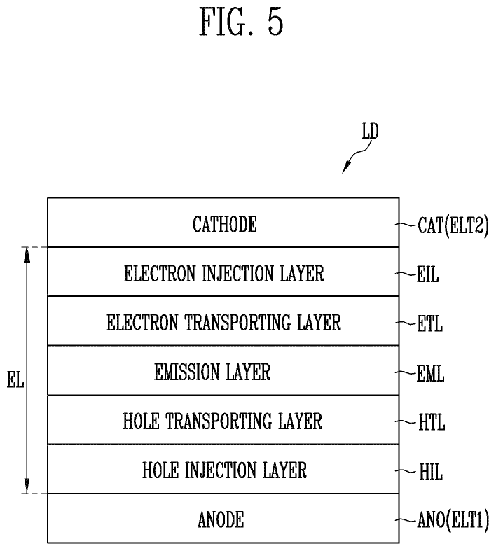

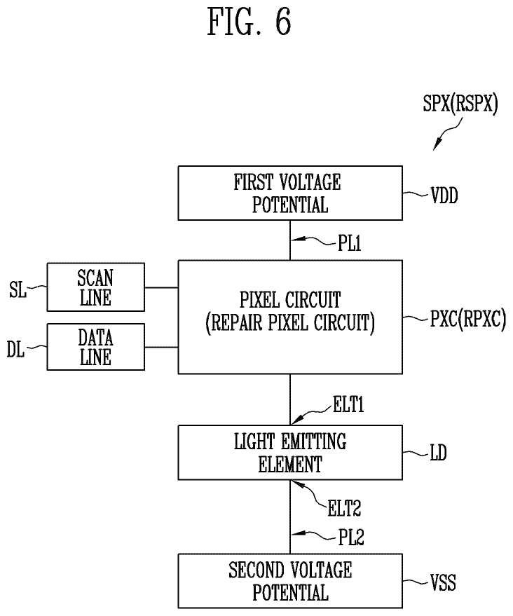

In some embodiments, the pixel array 110 may further comprise a repaired sub-pixel RSPX. For example, a repair process performed during manufacturing of the display device DD may start by inspecting and determining whether the sub-pixels SPX operate normally. A sub-pixel SPX determined to abnormally operate during the repair process may be repaired to be provided as the repaired sub-pixel RSPX. The sub-pixel SPX may be repaired to be electrically connected to an auxiliary or repair pixel circuit RPXC (see FIG. 6) instead of connected to a pixel circuit PXC (see FIG. 5).

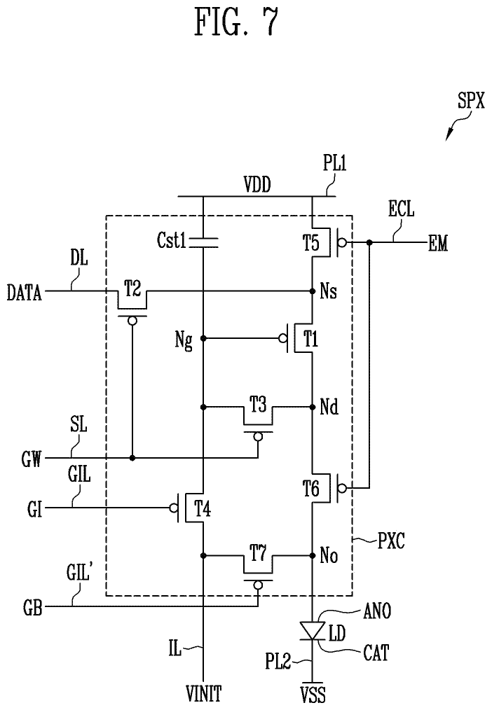

The scan driver 120 may be disposed at one side of the pixel array 110. The scan driver 120 may receive a first control signal SCS from the controller 140. The scan driver 120 may supply a scan signal GW (see FIG. 7) to the scan lines SL in response to the first control signal SCS, and thereby the scan driver 120 may provide the scan signal GW to the sub-pixels SPX.

The first control signal SCS may be a signal for controlling a drive timing of the scan driver 120. The first control signal SCS may comprise a scan start signal for the scan signal GW and a plurality of clock signals. The scan signal GW may be set to a gate-on level corresponding to a transistor (e.g., a switching transistor T2 and a compensation transistor T3 shown in FIG. 7) to which the corresponding scan signal GW is supplied.

The data driver 130 may be disposed at one side of the pixel array 110. The data driver 130 may receive a second control signal DCS from the controller 140. The data driver 130 may supply a data signal DATA (see FIG. 7) to one or more of the data lines in response to the second control signal DCS, and thereby the data driver 130 may provide the data signal DATA to the sub-pixels SPX. For example, the second control signal DCS may be provided to the sub-pixel SPX through the data line DL. The second signal DCS may be a signal for controlling a drive timing of the data driver 130.

A portion of each scan line SL may extend in a first direction DR1 to be electrically connected to a sub-pixel SPX of a corresponding pixel row through another portion of the scan line SL, which extends in a second direction DR2. Accordingly, each scan line SL may supply the scan signal GW to the sub-pixels SPX in a row corresponding to the scan line SL.

Each data line DL may extend along a pixel column (e.g., the second direction DR2 and may be electrically connected to a sub-pixel SPX in the pixel column. The data line DL may supply a data signal DATA to the sub-pixel SPX connected thereto.

A pixel row direction is a horizontal direction and may mean the first direction DR1. A pixel column direction is a vertical direction and may mean the second direction DR2. However, the disclosure is not limited thereto.

FIG. 1 illustrates an embodiment in which the scan driver 120, the data driver 130, and the controller 140 are distinguished from each other. However, at least some of the scan driver 120, the data driver 130, and the controller 140 may be integrated into one module or one integrated circuit (IC) chip.

Next, a sectional structure of a display device DD in accordance with an embodiment of the disclosure will be described with reference to FIGS. 2 to 5.

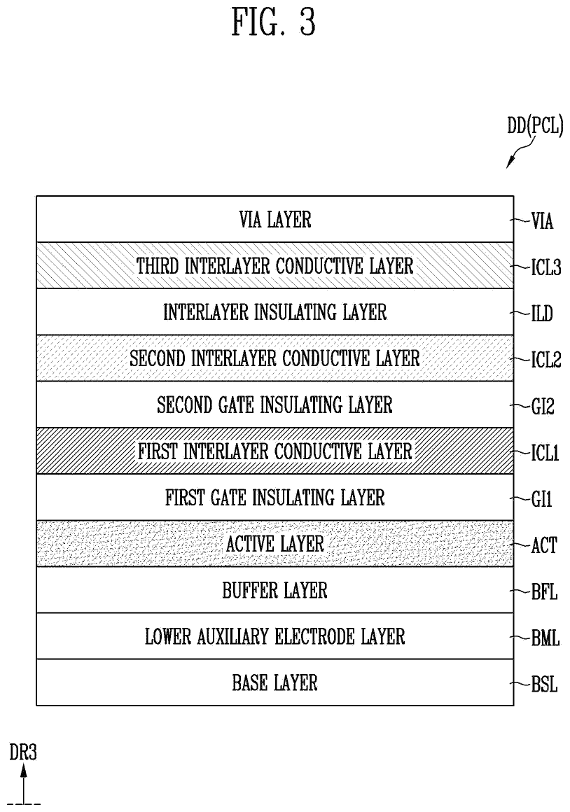

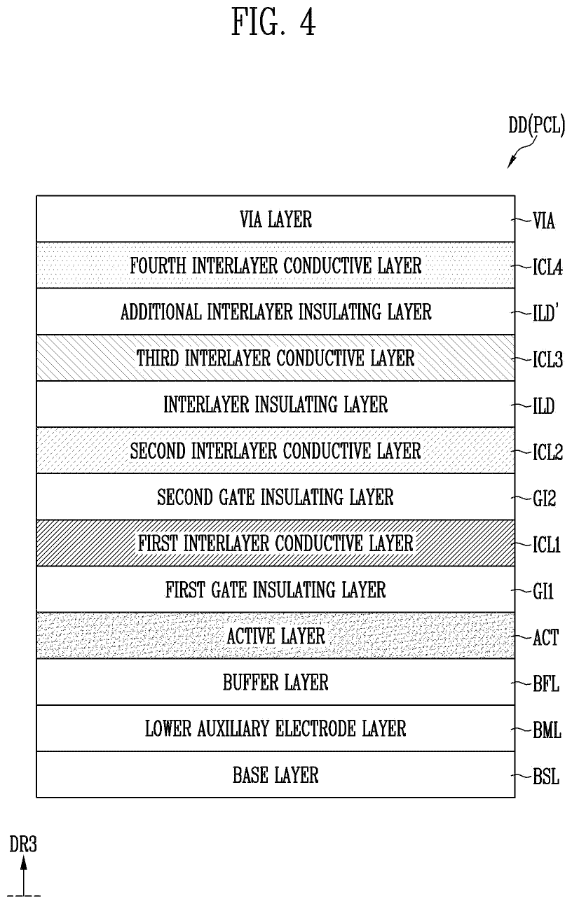

FIG. 2 is a schematic sectional view of a portion (e.g., a sub-pixel SPX) of a display device DD in accordance with an embodiment of the disclosure. FIGS. 3 and 4 are schematic sectional views illustrating a stacked structure of a pixel-circuit layer in accordance with an embodiment of the disclosure. FIG. 5 is a schematic sectional view illustrating a light emitting element in accordance with an embodiment of the disclosure.

Referring to FIGS. 2 and 5, the display device DD comprises a pixel-circuit layer PCL and a light-emitting-element layer LEL.

The pixel-circuit layer PCL may be a layer comprising a pixel circuit PXC (see FIG. 6) for driving light emitting elements LD. The pixel-circuit layer PCL may comprise a base layer BSL, conductive layers for forming pixel circuits, and insulating layers disposed on or among the conductive layers.

For example, a stacked structure in the display device DD (or the pixel-circuit layer PCL) in accordance with the embodiment of the disclosure illustrated in FIG. 3 may comprise a based layer BSL, a lower auxiliary electrode layer BML, a buffer layer BFL, an active layer ACT, a first gate insulating layer GI1, a first interlayer conductive layer ICL1, a second gate insulating layer GI2, a second interlayer conductive layer ICL2, an interlayer insulating layer ILD, a third interlayer conductive layer ICL3, and a via layer VIA, and the stacked structure may have a form obtained by patterning at least some of the layers in the structure as the above-described layers are sequentially stacked. In some embodiments, the stacked structure in the display device DD (or the pixel-circuit layer PCL) includes an additional interlayer insulating layer ILD′ and a fourth interlayer conductive layer ICL4 between the third interlayer conductive layer ICL3 and the via layer VIA (see FIG. 4). Hereinafter, for convenience of description, the stacked structure shown in FIG. 3 will be mainly described, and the stacked structure shown in FIG. 4 will be additionally described as a structure in accordance with an embodiment of the disclosure.

In subsequent drawings, a same layer as layers described above with reference to FIGS. 3 and 4 (e.g., patterning in a same process) may be expressed by using a same hatching.

The base layer BSL may form (or constitute) a base surface of the display device DD. The base layer BSL may comprise a rigid or flexible substrate or film.

For example, the base layer BSL may be a glass substrate or a base film comprising an organic material. The substance of the base layer BSL or the material constituting the base layer BSL is not limited to a specific example, and the base layer BSL may comprise various materials.

The buffer layer BFL may prevent impurities from diffusing into the active layer ACT or prevent moisture from infiltrating into the active layer ACT. In accordance with an embodiment, the buffer layer BFL may comprise at least one material selected from the group consisting of silicon nitride (SiNₓ), silicon oxide (SiOₓ), silicon oxynitride (SiOₓN_{y}), and aluminum oxide (AlOₓ). However, the disclosure is not necessarily limited to the above-described examples.

The active layer ACT may comprise a semiconductor. For example, the active layer ACT may comprise at least one semiconductor selected from the group consisting of polysilicon, Low Temperature Polycrystalline Silicon (LTPS), amorphous silicon, and an oxide semiconductor. In accordance with an embodiment, the active layer ACT may form channels of transistors, and an impurity may be doped into portions of the active layer ACT that contact source/drain electrodes.

The lower auxiliary electrode layer BML, the first interlayer conductive layer ICL1, the second interlayer conductive layer ICL2, the third interlayer conductive layer ICL3, and the fourth interlayer conductive layer ICL4 may comprise a conductive material. In accordance with an embodiment, each of the lower auxiliary electrode layer BML, the first interlayer conductive layer ICL1, the second interlayer conductive layer ICL2, the third interlayer conductive layer ICL3, and the fourth interlayer conductive layer ICL4 may comprise at least one conductive layer. In some embodiments, each of the lower auxiliary electrode layer BML, the first interlayer conductive layer ICL1, the second interlayer conductive layer ICL2, the third interlayer conductive layer ICL3, and the fourth interlayer conductive layer ICL4 may comprise at least one conductive material selected from the group consisting of gold (Au), silver (Ag), aluminum (AI), molybdenum (Mo), chromium (Cr), titanium (Ti), nickel (Ni), neodymium (Nd), copper (Cu), and platinum (Pt). However, the disclosure is not necessarily limited to the above-described example.

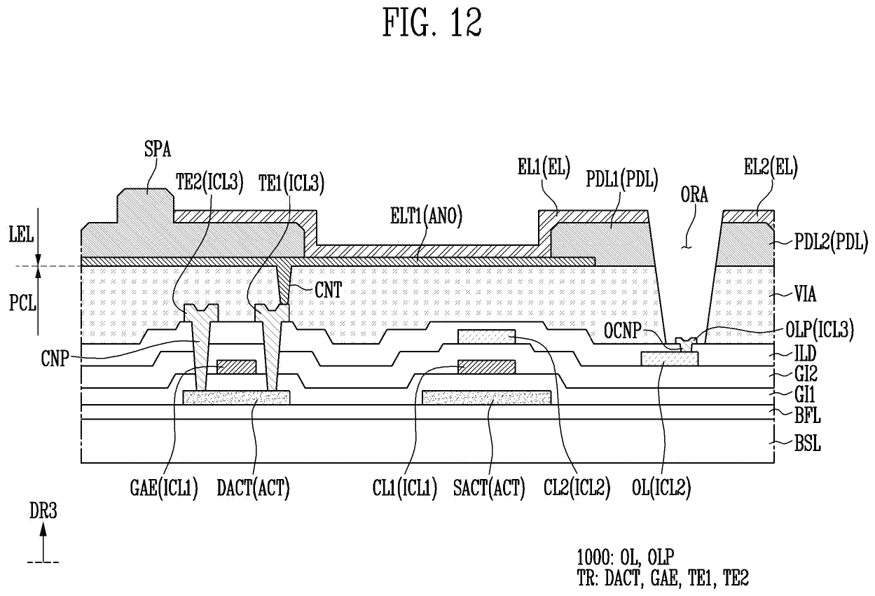

The first gate insulating layer GI1, the second gate insulating layer GI2, the interlayer insulating layer ILD, the additional interlayer insulating layer ILD′, and the via layer VIA may be disposed between the above-described conductive layers to electrically separate the conductive layers from each other. In accordance with an embodiment, the conductive layers may be electrically connected to each other where needed through a contact member CNP (see FIG. 12) formed in at least one of the first gate insulating layer GI1, the second gate insulating layer GI2, the interlayer insulating layer ILD, and the additional interlayer insulating layer ILD′. A conductive layer in the pixel-circuit layer PCL may be electrically connected to a conductive layer of the light-emitting-element layer LEL through a contact part CNT (see FIG. 12) formed in the via layer VIA. In some embodiments, the via layer VIA may be a planarization layer.

In accordance with an embodiment, the first gate insulating layer GI1, the second gate insulating layer GI2, the interlayer insulating layer ILD, and the additional interlayer insulating layer ILD′ may comprise an inorganic material. For example, the inorganic material may comprise at least one material selected from the group consisting of silicon nitride (SiNₓ), silicon oxide (SiOₓ), silicon oxynitride (SiOₓN_{y}), and aluminum oxide (AlₓO_{y}). In some embodiments, the via layer VIA may comprise an organic material. For example, an organic material may comprise at least one material selected from the group consisting of acrylic resin, epoxy resin, phenolic resin, polyamide resin, polyimide resin, unsaturated polyester resin, poly-phenylene ether resin, poly-phenylene sulfide resin, and benzocyclobutene (BCB). However, the disclosure is not necessarily limited to the above-described examples.

Returning to FIG. 2, the light-emitting-element layer LEL may be disposed on the pixel-circuit layer PCL. In some embodiments, the light emitting elements LEL may comprise a light emitting element LD, a pixel defining layer PDL, and an encapsulation layer TFE. In some embodiments, the light emitting element LD may be a light emitting diode comprising an organic material. For example, the light emitting element LD may be an Organic Light Emitting Diode (OLED).

The light emitting element LD may be disposed on the pixel-circuit layer PCL. In some embodiments, the light emitting element LD may comprise a first electrode ELT1, a light emitting part EL, and a second electrode ELT2. In some embodiments, the light emitting part EL may be disposed in an area defined by the pixel defining layer PDL. One surface of the light emitting part EL may be electrically connected to the first electrode ELT1, and the other surface of the light emitting part EL may be electrically connected to the second electrode ELT2.

The first electrode ELT1 may be an anode electrode ANO for the light emitting part EL, and the second electrode ELT2 may be a cathode electrode CAT for the light emitting part EL. In some embodiments, the first electrode ELT1 and the second electrode ELT2 may comprise a conductive material. For example, the conductive material may comprise at least one conductive material selected from the group consisting of gold (Au), silver (Ag), aluminum (AI), molybdenum (Mo), chromium (Cr), titanium (Ti), nickel (Ni), neodymium (Nd), copper (Cu), and platinum (Pt). Alternatively, in some embodiments, the conductive material may comprise at least one selected material from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO2), carbon nano tubes, and graphene. However, the disclosure is not necessarily limited thereto.

In some embodiments, the second electrode ELT2 may be manufactured to be entirely deposited in or covering a display area DA. Accordingly, power supplied to the second electrode ELT2 may be provided to each sub-pixel SPX.

The light emitting part EL may have a multi-layer thin film structure including a light generation layer (e.g., an emission layer EML) as shown in FIG. 5. The emission layer EML emits light by recombination of the injected electrons and holes. The light emitting part EL may also include a hole injection layer HIL for injecting holes and a hole transport layer HTL for increasing a hole recombination opportunity by suppressing movement of electrons. The light emitting part EL may further include an electron transport layer ETL for smoothly transporting the electrons to the emission layer EML and an electron injection layer EIL for injecting the electrons. The light emitting part EL may emit light, based on an electrical signal provided from the anode electrode ANO (e.g., the first electrode ELT1) and the cathode electrode CAT (e.g., the second electrode ELT2).

The pixel defining layer PDL may be disposed on the pixel-circuit layer PCL, to define positions where the light emitting parts EL are located. The pixel defining layer PDL may comprise an organic material. For example, the pixel defining layer PDL may comprise at least one organic material selected from the group consisting of acrylic resin, epoxy resin, phenolic resin, polyamide resin, and polyimide resin. However, the disclosure is not limited thereto. In another embodiment, the pixel defining layer PDL may comprise an inorganic material. For example, the pixel defining layer PDL may comprise at least one of silicon oxide (SiOₓ) and silicon nitride (SiNₓ). In some embodiments, the pixel defining layer PDL may have a multi-layer structure in which a layer comprising silicon oxide (SiOₓ) and a layer comprising silicon nitride (SiNₓ) are stacked.

The encapsulation layer TFE may be disposed on the light emitting element LD (e.g., the second electrode ELT2). The encapsulation layer TFE may be planarized or may otherwise reduce or eliminate a step difference caused by the light emitting element LD and the pixel defining layer PDL. The encapsulation layer TFE may comprise a plurality of insulating layers covering the light emitting element LD. In some embodiments, the encapsulation layer TFE may have a structure in which an inorganic layer and an organic layer are alternately stacked. In some embodiments, the encapsulation layer TFE may be a thin film encapsulation layer.

Hereinafter, a pixel circuit PXC and a repair pixel circuit RPXC in accordance with an embodiment of the disclosure will be described with reference to FIGS. 6 to 8. In some embodiments, the pixel circuit PXC may be designated as a first pixel circuit. The repair pixel circuit RPXC may be designated as an auxiliary pixel circuit or a second pixel circuit.

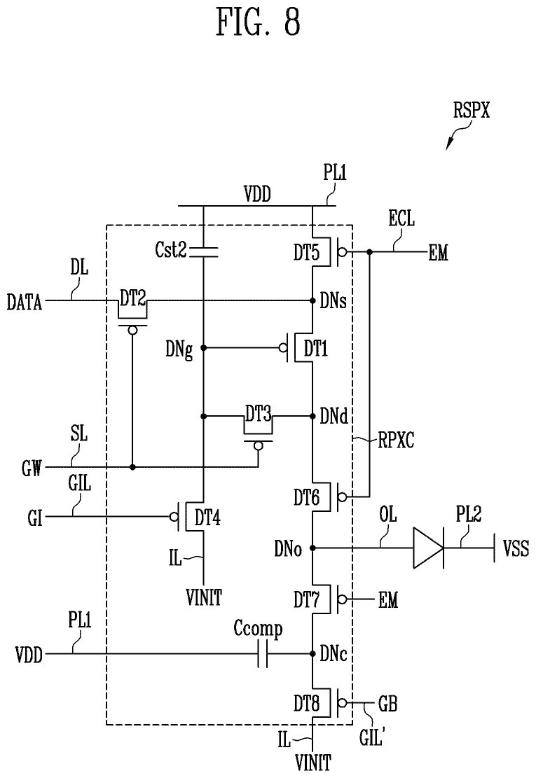

FIG. 6 illustrates a schematic connection structure of a pixel circuit PXC or a repair pixel circuit RPXC. FIG. 7 illustrates a pixel circuit in accordance with an embodiment of the disclosure FIG. 8 illustrates a repair pixel circuit in accordance with an embodiment of the disclosure. First, the schematic connection structure of the pixel circuit PXC or the repair pixel circuit RPXC will be described with reference to FIG. 6. Then, detailed embodiments will be described with reference to FIGS. 7 and 8.

FIG. 6 is a schematic block diagram illustrating an electrical connection structure of a light emitting element in accordance with an embodiment of the disclosure. For example, FIG. 6 may illustrate an electrical connection structure of a sub-pixel SPX or a repaired sub-pixel RSPX, and the electrical connection structure may use a pixel circuit PXC for the sub-pixel SPX or use a repair pixel circuit RPXC for the repaired sub-pixel circuit RSPX.

Referring to FIG. 6, the sub-pixel SPX may comprise a pixel circuit PXC configured to drive a light emitting element LD. The repaired sub-pixel RSPX may comprise a repair pixel circuit RPXC configured to drive a light emitting element LD.

The pixel circuit PXC (or the repair pixel circuit RPXC) may comprise at least one circuit element. For example, the pixel circuit PXC (or the repair pixel circuit RPXC) may comprise a driving transistor, a switching transistor, and a storage capacitor.

The pixel circuit PXC (or the repair pixel circuit RPXC) may be electrically connected to a scan line SL and a data line DL. The scan line SL may supply a scan signal GW to the pixel circuit PXC (or the repair pixel circuit RPXC). In some embodiments, the scan line SL may be electrically connected to a gate electrode of the switching transistor of the pixel circuit PXC (or the repair pixel circuit RPXC). The light emitting element LD may be configured to emit light corresponding to a data signal DATA provided from the data line DL.

The pixel circuit PXC may be electrically connected to a first power line PL1 and a second power line PL2. For example, a first electrode ELT1 of the light emitting element LD may be electrically connected to the pixel circuit PXC (or the repair pixel circuit RPXC) and the first power line PL1, and a second electrode ELT2 of the light emitting element LD may be electrically connected to the second power line PL2. The first power line PL1 and the second power line PL2 may be disposed on the base layer BSL.

A power source of the first power line PL1 and a power source of the second power line PL2 may have different potentials. For example, the power source of the first power line PL1 is a high-potential pixel power source supplying power at a first voltage potential VDD, and the power source of the second power line PL2 may be a low-potential pixel power source supplying power source at a second voltage potential VSS. A potential difference between the power source of the first power line PL1 and the power source of the second power line PL2 may be set to equal to higher than a threshold voltage of the light emitting elements LD.

The first power line PL1 may be electrically connected to the pixel circuit PXC (or the repair pixel circuit RPXC). The second power line PL2 may be electrically connected to a cathode electrode (e.g., the second electrode ELT2) of light emitting element LD.

In some embodiments, the second power line PL2 may be electrically connected to the second electrode ELT2. For example, a power source may apply power to the second electrode ELT2 through the second power line PL2 disposed in a non-display area NDA. Alternatively, a power source may apply power to the second electrode ELT2 through the second power line PL2 formed in the pixel-circuit layer PCL in the display area DA.

The light emitting elements LD may be connected in a forward-bias direction between the first power line PL1 and the second power line PL2, to respectively form effective light sources. These effective light sources may form the light emitting elements LD of the pixel circuit PXC (or the repair pixel circuit RPXC).

Each of the light emitting elements LD may emit light with a luminance corresponding to a driving current supplied through the pixel circuit PXC (or the repair pixel circuit RPXC). During each frame period, the pixel circuit PXC (or the repair pixel circuit RPXC) may supply a driving current corresponding to the data signal DATA to the light emitting element LD. The light emitting element LD may emit light with a luminance corresponding to a current flowing therethrough.

A sub-pixel SPX comprising a pixel circuit PXC in accordance with an embodiment of the disclosure will be described with reference to FIG. 7. The pixel circuit PXC in accordance with the embodiment of the disclosure may include seven transistors and one capacitor.

The sub-pixel SPX shown in FIG. 7 may be one of the sub-pixels SPX in an nth row of an array. The pixel circuit PXC in the sub-pixel SPX may be electrically connected to each of a scan line SL, a first initialization control line GIL, and an emission control line ECL, which correspond to the nth row. The scan line SL, the first initialization control line GIL, and the emission control line ECL respectively supply a scan signal GW, a first initialization control signal GI, and an emission control signal EM to the pixel circuit PXC. The pixel circuit PXC may receive a second initialization control signal GB through a second initialization control line GIL′ corresponding to the nth row.

The pixel circuit PXC may comprise a driving transistor T1, a switching transistor T2, a compensation transistor T3, an initialization transistor T4, an operation control transistor T5, an emission control transistor T6, a bypass transistor T7, and a storage capacitor Cst1.

A gate electrode of the driving transistor T1 may be electrically connected to a gate node Ng. A source electrode of the driving transistor T1 may be electrically connected to a source node Ns that the operation control transistor T5 connects to a first power line PL1. A drain electrode of the driving transistor T1 may be electrically connected to a drain node Nd that the emission control transistor T6 electrically connects to an anode electrode ANO of a light emitting element LD. A current flowing through the light emitting element LD may be determined by a voltage difference between the gate electrode and the source electrode of the driving transistor T1, and a luminance of the light emitting element LD may be determined based on the current.

A gate electrode of the switching transistor T2 may be electrically connected to the scan line SL. A first electrode of the switching transistor T2 may be electrically connected to a data line DL, and a second electrode of the switching transistor T2 may be electrically connected to the source node Ns and therefore to the source electrode of the driving transistor T1. The switching transistor T2 may be turned on according to the scan signal GW transferred through the scan line SL, and when turned on, the switching transistor T2 transfers a data signal DATA from the data line DL to the source electrode of the driving transistor T1. The data signal DATA may be transferred to the gate electrode of the driving transistor T1 by the compensation transistor T3 simultaneously turned on with the switching transistor T2.

A gate electrode of the compensation transistor T3 may be electrically connected to the scan line SL. A first electrode of the compensation transistor T3 may be electrically connected to the drain electrode of the driving transistor T1, and a second electrode of the compensation transistor T3 may be electrically connected to the gate node Ng. The compensation transistor T3 may be turned on according to the scan signal GW transferred through the scan line SL, to electrically connect the gate electrode and the drain electrode of the driving transistor T1 to each other. Therefore, the compensation transistor T3 may allow the driving transistor T1 to be diode-connected and thereby compensate for a threshold voltage Vth of the driving transistor T1.

A gate electrode of the initialization transistor T4 may be electrically connected to the first initialization control line GIL. A first electrode of the initialization transistor T4 may be electrically connected to an initialization voltage line IL, and a second electrode of the initialization transistor T4 may be electrically connected to the gate node Ng. The initialization transistor T4 may be turned on according to the first initialization control signal GI applied from the first initialization control line GIL, to transfer an initialization voltage VINIT to the gate node Ng. Therefore, the gate node Ng may be initialized. The initialization voltage VINIT may be set at a voltage higher than a second voltage potential VSS or may be the second voltage potential VSS.

A gate electrode of the operation control transistor T5 may be electrically connected to the emission control line ECL. A first electrode of the operation control transistor T5 may be electrically connected to the first power line PL1, and a second electrode of the operation control transistor T5 may be electrically connected to the source electrode of the driving transistor T1.

A gate electrode of the emission control transistor T6 may be electrically connected to the emission control line ECL. A first electrode of the emission control transistor T6 may be electrically connected to the drain electrode of the driving transistor T1, and a second electrode of the emission control transistor T6 may be electrically connected to the anode electrode ANO of the light emitting element LD through an output node No. The operation control transistor T5 and the emission control transistor T6 may be simultaneously turned on according to the emission control signal EM applied from the emission control line ECL. Therefore, a first voltage potential VDD may be applied to the driving transistor T1, and a driving current may flow through the light emitting element LD.

A gate electrode of the bypass transistor T7 may be electrically connected to the second initialization control line GIL′. A first electrode of the bypass transistor T7 may be electrically connected to the anode electrode ANO of the light emitting element LD through the output node No, and a second electrode of the bypass transistor T7 may be electrically connected to the initialization voltage line IL to be supplied with the initialization voltage VINIT. The bypass transistor T7 may be turned on by the second initialization control signal GB applied from the second initialization control line GIL′ to initialize the anode electrode ANO of the light emitting element LD. The second initialization control signal GB may be the same signal as the first initialization control signal GI or may be a signal different from the first initialization control signal GI.

The storage capacitor Cst1 may be electrically connected between the first power line PL1 and the gate node Ng. A voltage between the first voltage potential VDD and the gate node Ng may be stored in the storage capacitor Cst1.

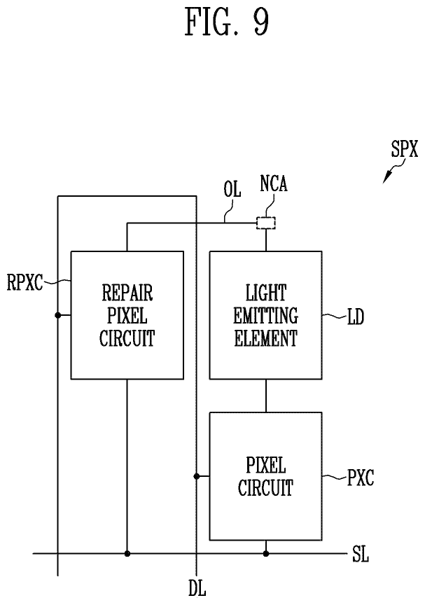

The anode electrode ANO of the light emitting element LD may be configured to be electrically connected to a line part (see FIG. 9) and may be configured to be electrically separated from the pixel circuit PXC. This will be described in detail later with reference to drawings subsequent to FIG. 9. A cathode electrode CAT of the light emitting element LD may be electrically connected to a second power line PL2 to which the second voltage potential VSS is applied.

A repaired sub-pixel RSPX comprising a repair pixel circuit RPXC in accordance with an embodiment of the disclosure will be described with reference to FIG. 8. The repair pixel circuit RPXC in accordance with this embodiment may comprise eight transistors and two capacitors.

The repaired sub-pixel RSPX shown in FIG. 8 may be one of the sub-pixels in the nth row, and the repaired sub-pixel RSPX may be repaired or made operable by a repair process. The repair pixel circuit RPXC in the repaired sub-pixel RSPX may be electrically connected to each of a scan line SL, a first initialization control line GIL, and an emission control line ECL, which correspond to the nth row, and the scan line SL, the first initialization control line GIL, and the emission control line may respectively supply a scan signal GW, a first initialization control signal GI, and an emission control signal EM to the repair pixel circuit RPXC.

The repaired sub-pixel RSPX may comprise a repair pixel circuit RPXC, and the repair pixel circuit RPXC may comprise a driving transistor DT1, a switching transistor DT2, a compensation transistor DT3, an initialization transistor DT4, an operation control transistor DT5, an emission control transistor DT6, a capacitance control transistor DT7, a capacitive element initialization transistor DT8, a storage capacitor Cst2, and a compensation capacitor Ccomp.

The elements DT1, DT2, DT3, DT4, DT5, DT6, and Cst2 of the repair pixel circuit RPXC of FIG. 8 may have sizes and capacities, which are different from sizes and capacities of the corresponding elements T1, T2, T3, T4, T5, T6, and Cst1 of the pixel circuit PXC of FIG. 7. The repair pixel circuit RPXC of the repaired sub-pixel RSPX is mostly identical to the pixel circuit PXC of the sub-pixel SPX shown in FIG. 7, except for some differences. Hereinafter, descriptions that are the same as described above for corresponding elements in FIG. 7 will not be repeated, and the differences between the repaired subpixel RSPX and the sub-pixel SPX will mainly be described.

In the repair pixel circuit RPXC, a gate electrode of the capacitance control transistor DT7 may be electrically connected to the emission control line ECL to be supplied with the emission control signal EM. A first electrode of the capacitance control transistor DT7 may be electrically connected to a line part OL through an output node DNo, and a second electrode of the capacitance control transistor DT7 may be electrically connected to a compensation node DNc. The capacitance control transistor DT7 may be turned on according to the emission control signal EM, to supply energy stored in the compensation capacitor Ccomp to the line part OL.

A gate electrode of the capacitive element initialization transistor DT8 may be electrically connected to a second initialization control line GIL′ to be supplied with a second initialization control signal GB. A first electrode of the capacitive element initialization transistor DT8 may be electrically connected to the compensation node DNc, and a second electrode of the capacitive element initialization transistor DT8 may be electrically connected to an initialization voltage line IL. The capacitive element initialization transistor DT8 may be turned on according to the second initialization control signal GB, and the initialization voltage VINIT may be supplied to the compensation capacitor Ccomp such that a charge quantity corresponding to a difference between the first voltage potential VDD and the initialization voltage VINIT can charge the compensation capacitor Ccomp.

The first voltage potential VDD and a voltage of the compensation node DNc may be applied to opposite ends of the compensation capacitor Ccomp, and charges corresponding to a voltage difference between the ends may be stored in the compensation capacitor Ccomp.

A light emitting element LD of the repaired sub-pixel RSPX may be electrically connected to the repair pixel circuit RPXC through the line part OL and may be configured to normally emit light. For example, the line part OL may be electrically connected to the output node DNo between the capacitance control transistor DT7 and the capacitive element initialization transistor DT8.

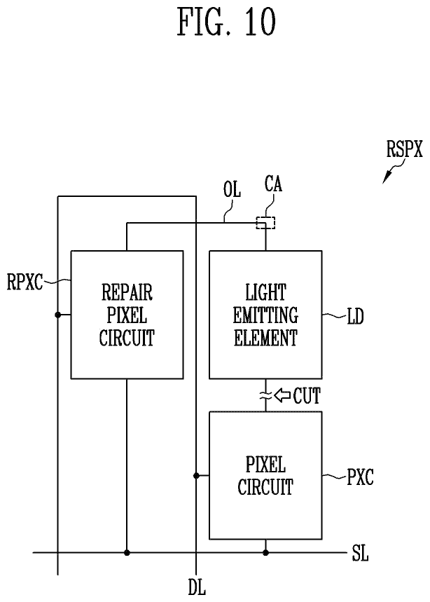

An electrical connection structure of a pixel circuit PXC or a repair pixel circuit RPXC with respect to a light emitting element LD in accordance with an embodiment of the disclosure will be described with reference to FIGS. 9 and 10.

FIG. 9 is a schematic view illustrating a structure in which a light emitting element is electrically connected to a pixel circuit in accordance with an embodiment of the disclosure. FIG. 10 is a schematic view illustrating a structure in which a light emitting element is electrically connected to a repair pixel circuit in accordance with an embodiment of the disclosure.

Referring to FIGS. 9 and 10, the light emitting element LD may be electrically connected to the pixel circuit PXC or the repair pixel circuit RPXC to emit light.

A scan line SL may be electrically connected to the pixel circuit PXC and the repair pixel circuit RPXC. A data line DL may be electrically connected to the pixel circuit PXC and the repair pixel circuit RPXC. For example, a scan line SL for one pixel row may be electrically connected to each of a corresponding pixel circuit PXC and a corresponding repair pixel circuit RPXC.

Similarly, a data line DL for supplying a data signal DATA may be electrically connected to each of a corresponding pixel circuit PXC and a corresponding repair pixel circuit RPXC.

In some embodiments (FIG. 9), the light emitting element LD of the sub-pixel SPX may be electrically connected to the pixel circuit PXC and may not be electrically connected to the repair pixel circuit RPXC. The sub-pixel SPX of FIG. 9 may be one of sub-pixels SPX on which a repair process is not performed.

For example, the light emitting element LD may be supplied with a driving current from the pixel circuit PXC. A line part OP electrically connected to the repair pixel circuit RPXC may not be electrically connected to the light emitting element LD because a non-connection area NCA is interposed between the repair pixel circuit RPXC and the light emitting element LD. The non-connection area NCA may be defined between an anode electrode ANO of the light emitting element LD and the line part OL.

In some embodiments (FIG. 10), the light emitting element LD of the repair pixel circuit RSPX may be electrically connected to the repair pixel circuit RPXC and may not be electrically connected to the pixel circuit PXC. The repaired sub-pixel RSPX may be provided or configured when the repair process is performed.

When the repair pixel circuit RPXC is connected to the light emitting element, the light emitting element LD may be supplied with a driving current from the repair pixel circuit RPXC. The line part OL electrically connected to the repair pixel circuit RPXC may be electrically connected to the light emitting element LD through (e.g., via) a connection area CA. The connection area CA of FIG. 10 may correspond to the non-connection area NCA of FIG. 9, but the repair process may turn the non-connection area NCA to the connection area CA. For example, the connection area CA and the non-connection area NCA may be substantially the same structure but reconfigured by the repair process. As the repair process is performed, lines in the non-connection area NCA may be electrically connected to each other, and accordingly, the connection area CA may be manufactured. In addition, the light emitting element LD of the repaired sub-pixel RSPX may be electrically separated from the pixel circuit PXC. For example, at least some of lines electrically connecting the pixel circuit PXC and the anode electrode ANO of the light emitting element LD to each other may be cut during the repair process creating the repaired sub-pixel RSPX.

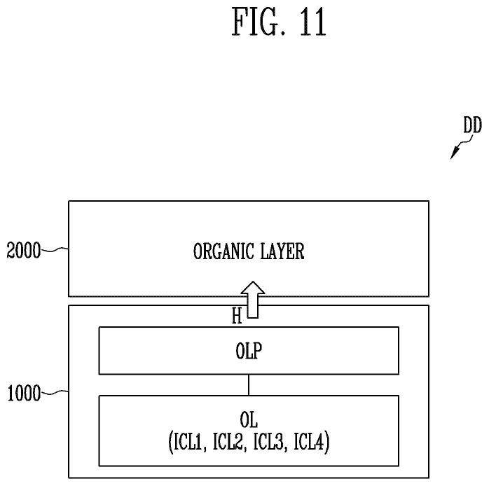

In accordance with an aspect of the disclosure, the line part OL may serve as not only a repair line for performing the repair process but may also serve as at least a portion of an organic layer removing part for preventing a risk such as a leakage current between sub-pixels SPX. This will be described with reference to FIGS. 11 to 13.

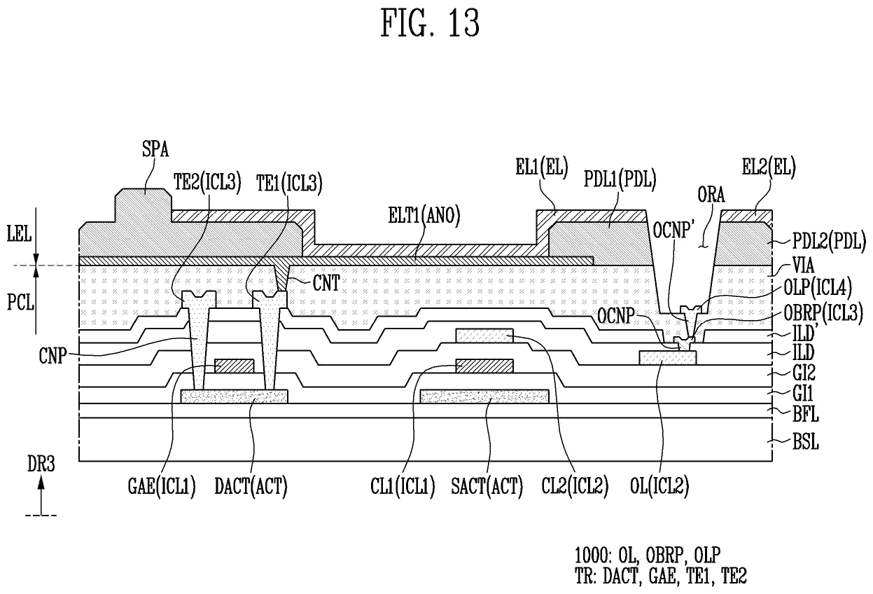

FIG. 11 is a view schematically illustrating an organic layer removing process in accordance with an embodiment of the disclosure. FIGS. 12 and 13 schematically illustrate a sectional structure of a display device DD comprising an organic layer removing part.

Referring to FIGS. 11 to 13, the display device DD may comprise an organic material removing part 1000. The organic material removing part 1000 may comprise a line part OL and an electrode part OLP.

In accordance with an embodiment, the organic material removing part 1000 may remove at least a portion of an organic layer 2000 disposed on the electrode part OLP. The organic layer 2000 may comprise a layer (e.g., a via layer VIA) comprising an organic material, which is disposed at an upper side of a pixel-circuit layer PCL, and a layer (e.g., a light emitting part EL and a pixel defining layer PDL) comprising an organic layer as at least a portion disposed on the pixel-circuit layer PCL.

In an embodiment, the electrode part OLP may be electrically connected to the line part OL. The electrode part OLP may receive an electrical signal supplied to the line part OL. For example, when an electrical pulse input is applied to the line part OL, energy based on the applied pulse input may be released from the electrode part OLP. Thermal energy generated by Joule heating H may be applied to an area disposed on the electrode part OLP, and accordingly, at least a portion of the organic layer 1000 overlapping with the electrode part OLP may be removed.

In some embodiments, the line part OL may be formed by at least one of the conductive layers in the pixel-circuit layer PCL. For example, the line part OL may be formed by at least one of a first interlayer conductive layer ICL1, a second interlayer conductive layer ICL2, a third interlayer conductive layer ICL3, and a fourth interlayer conductive layer ICL4. Hereinafter, for convenience of description, an embodiment in which the second interlayer conductive layer ICL2 forms the line part OL will be mainly described.

The electrode part OLP may be formed through a process different from a process that forms the line part OL, and the electrode part OLP may be disposed in a layer different from a layer in which the line part OL is disposed. For example, the electrode part OLP is a layer patterned in a process later than the process forming the line part OL, and the electrode part OLP may be closer to the organic layer 2000 than is the line part OL. However, the disclosure is not necessarily limited thereto. For example, the line part OL and the electrode part OLP may be integrally formed. In some embodiments, the line part OL and the electrode part OLP are integrally formed, and the electrode part OLP may include a structure protruding from the line part OL.

Hereinafter, for convenience of description, a first embodiment includes a structure in which the electrode part OLP is formed by the third interlayer conductive layer ICL3 and a second embodiment includes a structure in which the electrode part OLP is formed by the fourth interlayer conductive layer ICL4 will be described.

Referring to FIGS. 12 and 13, the pixel-circuit layer PCL may include circuit elements and insulating layers, which are in the pixel circuit PXC described above, and further includes a line part OL and an electrode part OLP. For convenience of description, an adjacent transistor TR as a circuit element, which may be the emission control transistor T6 or the bypass transistor T7, is illustrated in FIGS. 12 and 13, and illustration of layers (e.g., a second electrode ELT2) disposed on the light emitting part EL is omitted such that an arrangement relationship between components can be clearly understood.

The adjacent transistor TR may be roughly adjacent to a first electrode ELT1 (e.g., an anode electrode ANO) of a light emitting element LD to be electrically connected to the first electrode ELT1 of the light emitting element LD.

The adjacent transistor TR may comprise a first active layer DACT formed by an active layer ACT, a first gate electrode GAE formed by the first interlayer conductive layer ICL1, a first transistor electrode TE1 formed by the third interlayer conductive layer ICL3, and a second transistor electrode TE2 formed by the third interlayer conductive layer ICL3.

In some embodiments, the pixel-circuit layer PCL may further comprise a second active layer SCAT formed by the active layer ACT. The second active layer SACT may be part of the switching transistor T2.

In some embodiments, the pixel-circuit layer PCL may comprise a first conductive line CL1 formed by the first interlayer conductive layer ICL1 and a second conductive line CL2 formed by the second interlayer conductive layer ICL2. The first conductive line CL1 and the second conductive line CL2 may form a conductive structure for forming the pixel circuit PXC and the like.

The line part OL may overlap with the electrode part OLP in a plan view and be electrically connected to the electrode part OLP through a connection contact part OCNP. The connection contact part OCNP may penetrate an interlayer insulating layer ILD. In some embodiments, the line part OL may be formed by the second interlayer conductive layer ICL2.

In this specification, the term “in a plan view” may be defined with respect to a plane on which a base layer BSL is disposed. For example, the term “in a plan view” may be defined with respect to a plane extending in the first direction DR1 and the second direction DR2. For example, the term “in a plan view” may be defined with respect to a plane of which normal direction is a third direction DR3.

The electrode part OLP may be disposed on the line part OL. The electrode part OLP may occupy an area relatively narrower than an area that the line part OL occupies. For example, the line part OL may extend in one direction (e.g., the first direction DR1), and the electrode part OLP may be locally disposed in smaller areas overlapping the area in which the line part OL is disposed. The electrode part OLP may be a portion of the third interlayer conductive layer ICL3.

In some embodiments, the organic material removing part 1000 may further comprise a bridge part OBRP (see FIG. 13). For example, the line part OL may be electrically connected to the bridge part OBRP through the connection contact part OCNP, and the electrode part OLP may be electrically connected to the bridge part OBRP through an additional connection contact part OCNP′. In some embodiments, the bridge part OBRP may be formed by the third interlayer conductive layer ICL3, and the electrode part OLP may be formed by the fourth interlayer conductive layer ICL4. In some embodiments, in this structure, the first transistor electrode TE1 and the second transistor electrode TE2 may be formed by the fourth interlayer conductive layer ICL4. In some embodiments, the first transistor electrode TE1 is a source electrode or a drain electrode and is electrically connected to the first electrode ELT1 through a contact part CNT formed in the via layer VIA.

In a plan view, the line part OL and the electrode part OLP may not overlap with a partial area of the light emitting part EL overlapping with the first electrode ELT1. In a plan view, the line part OL and the electrode part OLP may not overlap with an area in which the first electrode ELT1 and the light emitting part EL are electrically in contact with each other. The line part OL and the electrode part OLP may not overlap with the first electrode ELT1 in a plan view.

At least a portion of the line part OL may overlap with the via layer VIA in a plan view, and at least another portion of the line part OL may not overlap with the via layer VIA in a plan view. The electrode part OLP may not overlap with the via layer VIA in a plan view. The line part OL and the electrode part OLP may overlap with an organic material removed area ORA in a plan view.

The organic material removed area ORA may mean an area (or space) in which the organic layer 2000 is removed by the thermal energy supplied by the electrode part OLP.

For example, the pixel defining layer PDL may not overlap with the organic material removed area ORA in a plan view. The pixel defining layer PDL may comprise regions, particularly a first pixel defining layer PDL1 and a second pixel defining layer PDL2, which are spaced apart from each other in a plan view with the organic material removed area ORA interposed between the first pixel defining layer PDL1 and the second pixel defining layer PDL2. The pixel defining layer PDL may not overlap with the electrode part OLP in a plan view. The first pixel defining layer PDL1 may be a first organic layer, and the second pixel defining layer PDL2 may be a second organic layer.

In an embodiment, the light emitting part EL, in a plan view, may not overlap with the organic material removed area ORA. The light emitting part EL may include a first light emitting part EL1 and a second light emitting part EL2, which in a plan view are spaced apart from each other with the organic material removed area ORA interposed therebetween. The light emitting part EL may not overlap with the electrode part OLP in a plan view. The first light emitting part EL1 may be a first region of the organic layer, and the second light emitting part EL2 may be a second region of the organic layer.

In accordance with an embodiment, the first light emitting part EL1 and the second light emitting part EL2 may be light emitting parts EL of different sub-pixels SPX.

Experimentally, it may be necessary for different electrical signals (e.g., currents having different intensities) to be supplied to adjacent sub-pixels SPX. However, when light emitting parts EL of sub-pixels SPX adjacent to each other are electrically connected to each other, carriers (e.g., electrons or holes) formed in the respective light emitting parts EL may be moved to each other, and electrical signals may be mixed. Therefore, a leakage current may be generated between the sub-pixels SPX.

However, in accordance with an embodiment, as the organic material removing part 1000 removes the organic layer 2000, the light emitting parts EL of the sub-pixels SPX adjacent to each other may be separated from each other. Thus, carriers cannot move between the adjacent light emitting parts EL, and the risk that electrical signals will be mixed can be reduced. In addition, as the color reproducibility of the sub-pixels SPX is improved, a high-quality display device structure can be provided, and the reliability of an electrical signal can be improved.

Moreover, a portion of the organic material removing part 1000 for implementing such a quality improvement structure may comprise a repair line for performing a repair process. That is, the repair line and an organic material removing structure can be implemented using a single structure. Hence, the complexity of lines is decreased, and a manufacturing process is simplified, so that process cost can be reduced. In particular, as the complexity of lines is decreased, a more thorough or compact line structure can be designed. Hence, the display device having a higher resolution can be ultimately implemented.

Meanwhile, in some embodiments, a light-emitting-element layer LEL may further comprise a spacer SPA formed on the pixel defining layer PDL. In some embodiments, the spacer SPA may have a structure protruding in the third direction DR3, and the light emitting part EL may be disposed at one side with respect to the spacer SPA. The light emitting part EL may not be disposed at the other side of the spacer SPA.

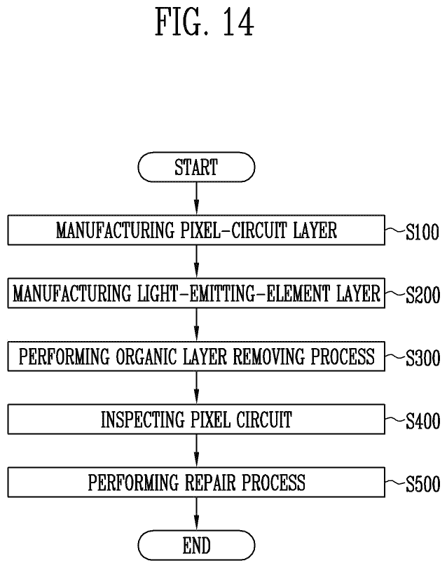

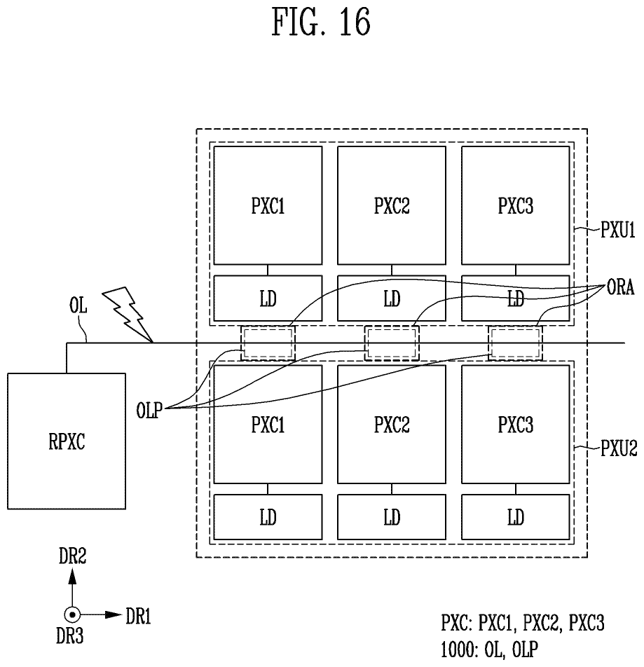

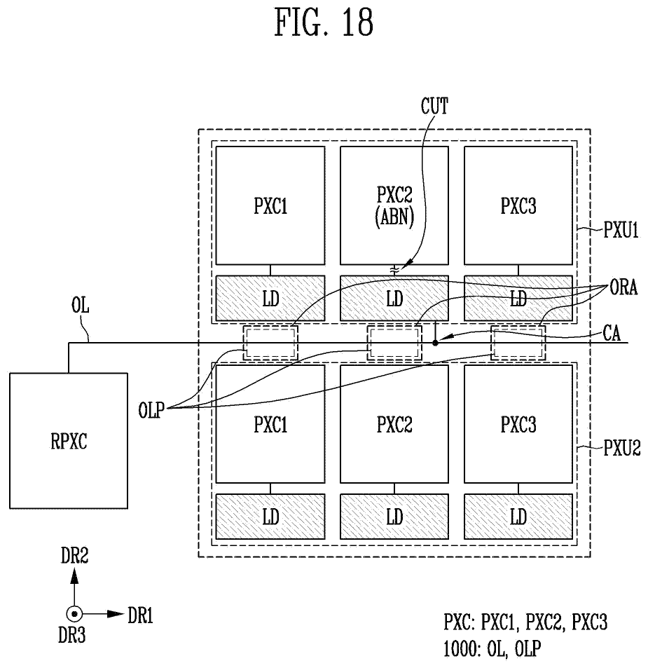

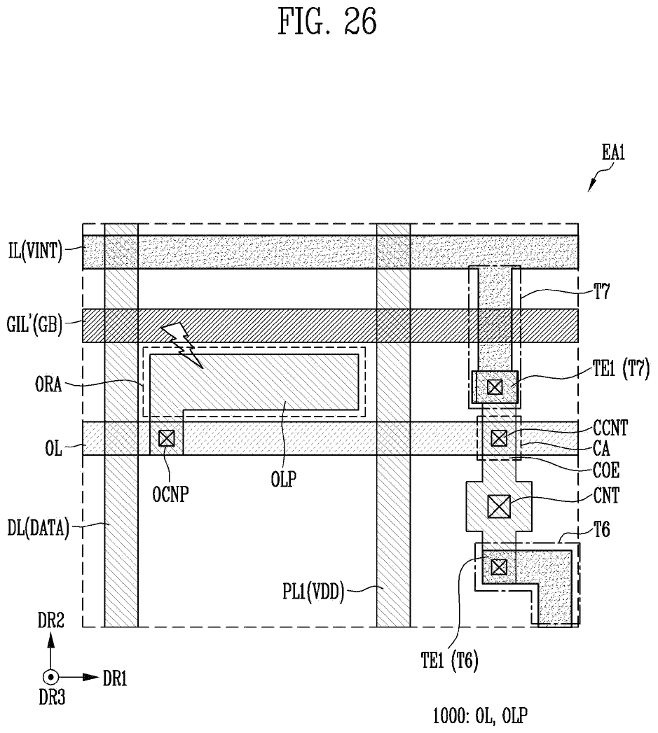

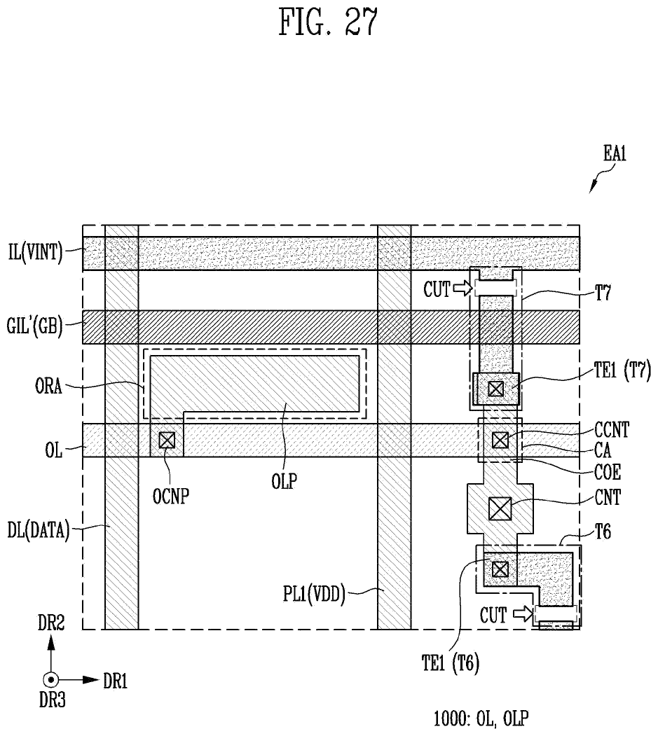

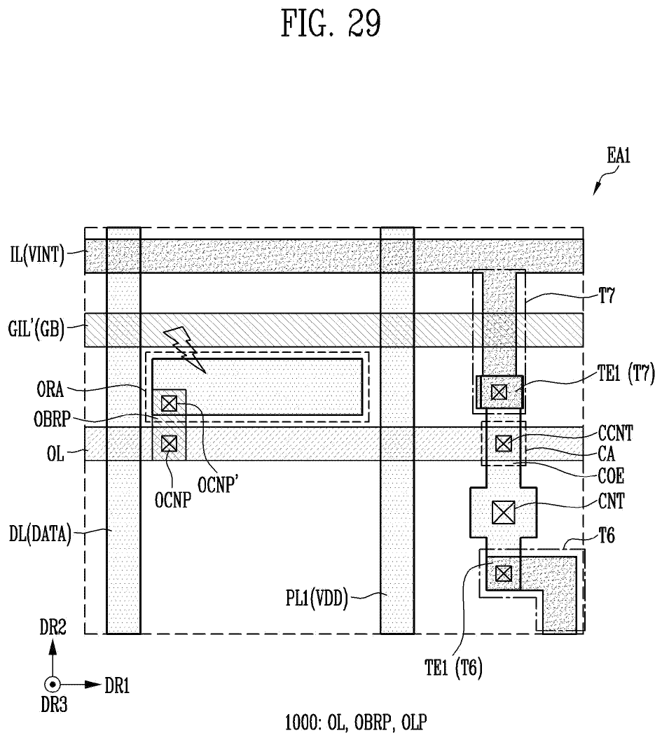

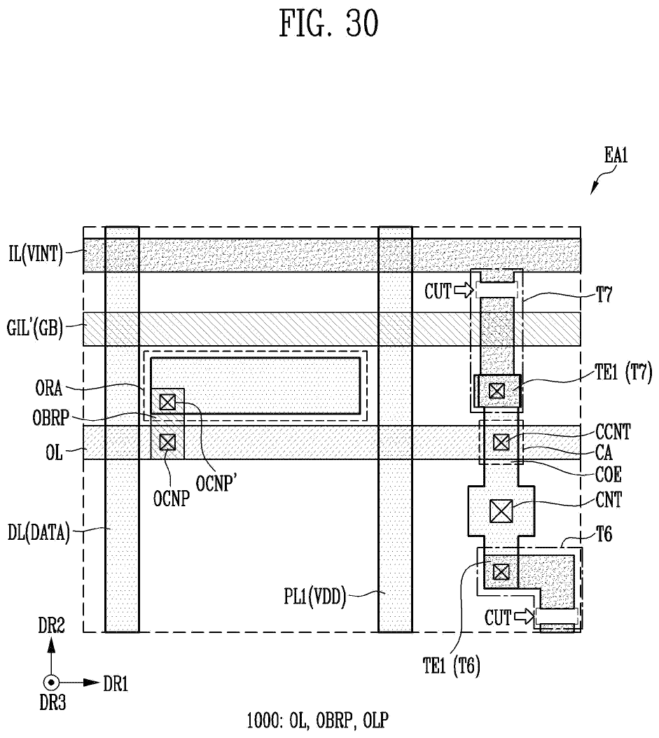

Hereinafter, a method of manufacturing a display device DD in accordance with an embodiment of the disclosure will be described with reference to FIGS. 14 to 30. In FIGS. 14 to 30, portions overlapping with those described above will be briefly described or will not be repeated.

FIG. 14 is a schematic flowchart illustrating a method of manufacturing a display device in accordance with an embodiment of the disclosure. FIGS. 15 to 30 are schematic views illustrating the method in accordance with the embodiment of the disclosure.

FIGS. 15 to 18 may be schematic block diagrams illustrating the method of manufacturing the display device DD in accordance with the embodiment of the disclosure.

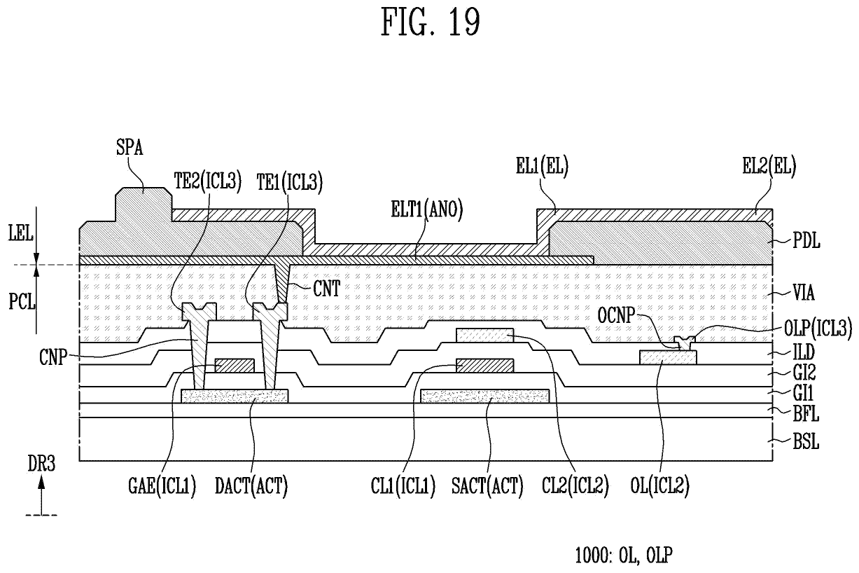

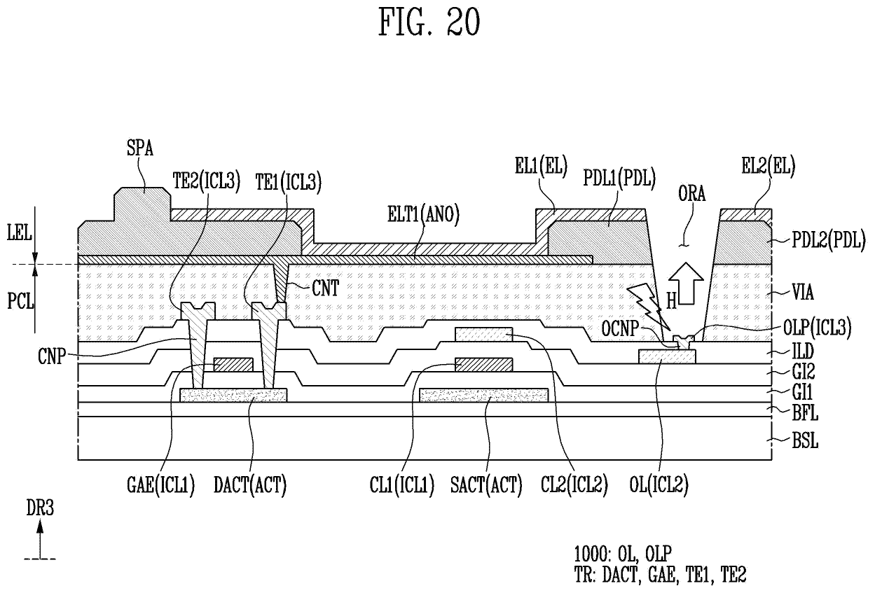

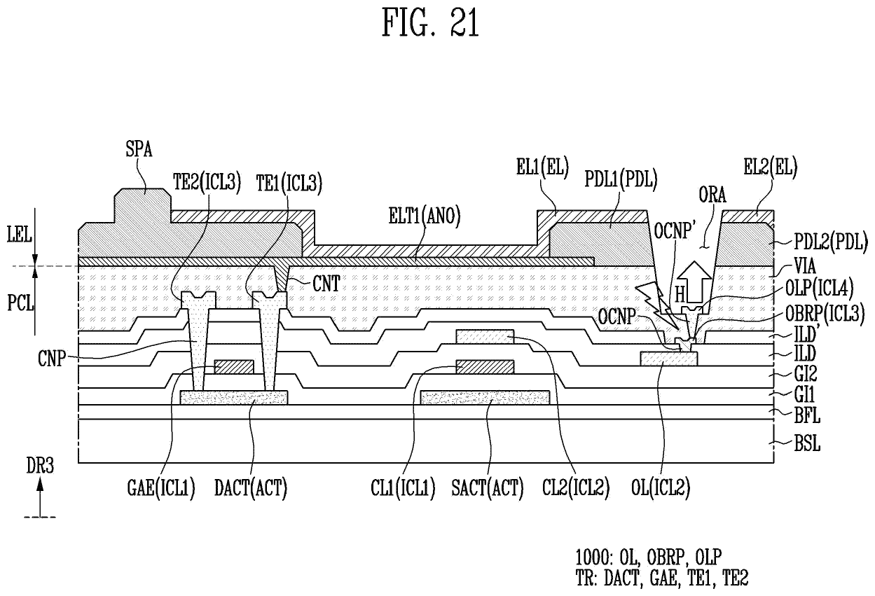

FIGS. 19 to 21 may be schematic sectional views illustrating the method of manufacturing the display device DD in accordance with the embodiment of the disclosure. FIGS. 19 and 20 illustrate sectional structures corresponding to the sectional structure described above with reference to FIG. 12, and FIG. 21 illustrates a sectional structure corresponding to the sectional structure described above with reference to FIG. 13.

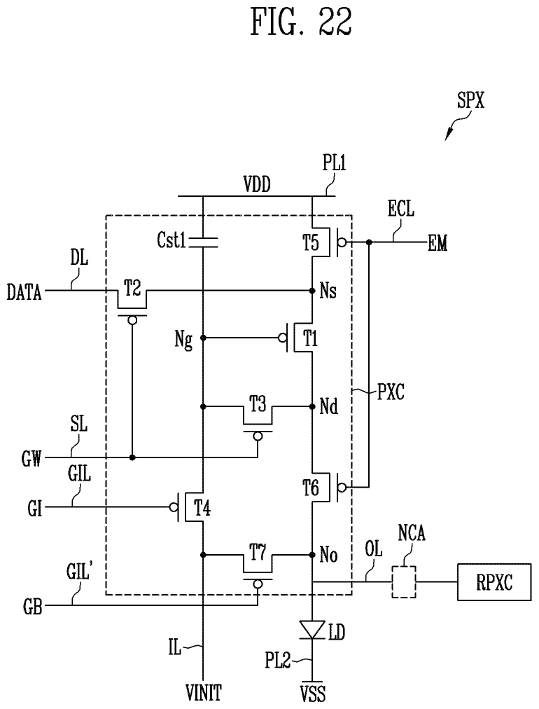

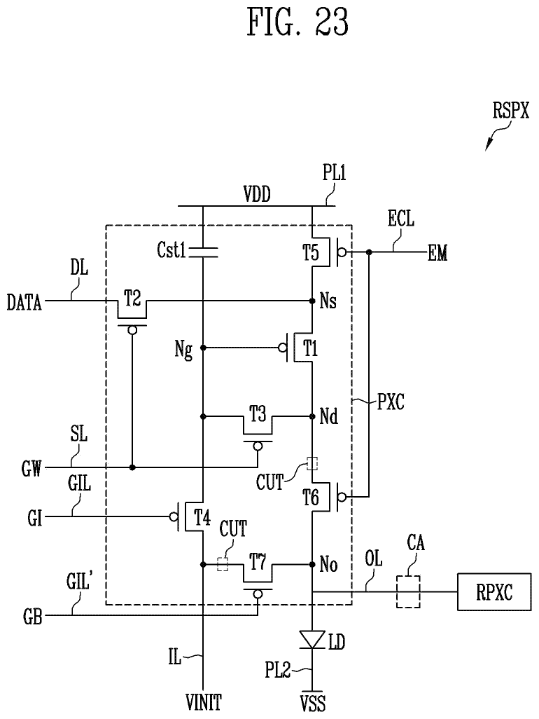

FIGS. 22 and 23 are circuit diagrams illustrating some steps of the method of manufacturing the display device DD in accordance with the embodiment of the disclosure. FIGS. 22 and 23 illustrate a connection relationship between a repair pixel circuit RPXC and a light emitting element LD.

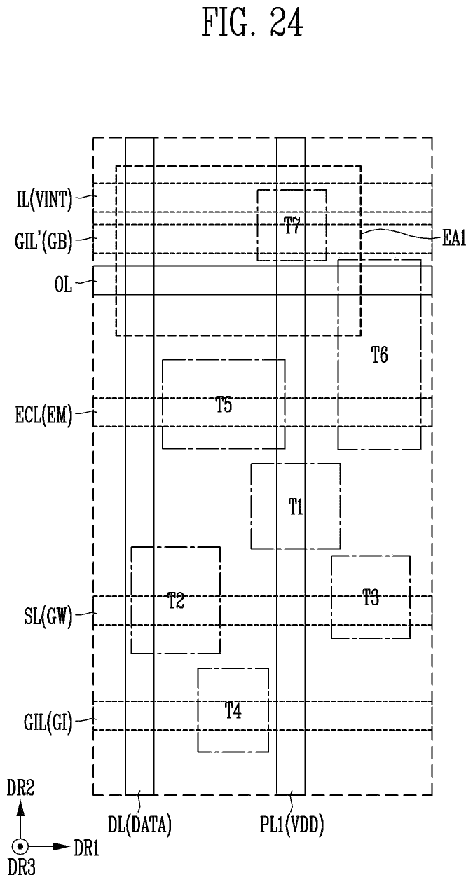

FIGS. 24 to 30 are schematic plan views illustrating the method of manufacturing the display device DD in accordance with the embodiment of the disclosure and are plan views based on a pixel circuit PXC. FIG. 24 schematically illustrates circuit elements of the pixel circuit PXC and lines electrically connected thereto.

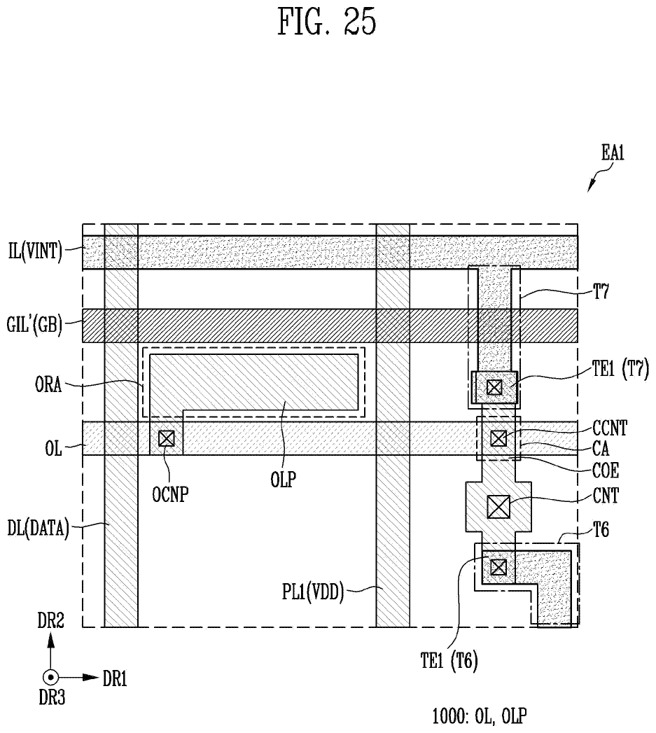

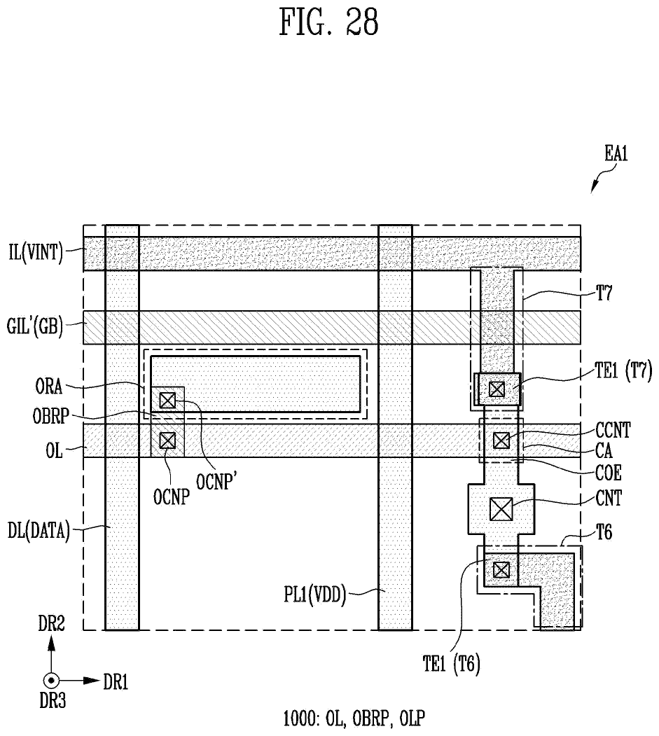

FIGS. 25 to 30 may be schematic enlarged views of area EA1 shown in FIG. 24. FIGS. 25 to 27 are schematic process plan views illustrating the method of manufacturing the display device DD in accordance with the embodiment of the disclosure and illustrate the planar structure of the embodiment described above with reference to FIG. 12. FIGS. 28 to 30 are schematic process plan views illustrating the method of manufacturing the display device DD in accordance with the embodiment of the disclosure and illustrate a planar structure of the embodiment described above with reference to FIG. 13.

The method of manufacturing the display device DD in accordance with the embodiment of the disclosure may comprise a process step for manufacturing the display device and an inspection step for the display device DD. For example, referring to FIG. 14, the method of manufacturing the display device DD in accordance with the embodiment of the disclosure may comprise step S100 of manufacturing a pixel-circuit layer, step S200 of manufacturing a light-emitting-element layer, step S300 of performing an organic layer removing process, step S400 of inspecting a pixel circuit, and step S500 of performing a repair process.

Referring to FIGS. 14, 15, 19, 24, 25, and 28, in the step S100 of manufacturing the pixel-circuit layer, a base layer BSL may be prepared, and a pixel-circuit layer PCL comprising a line part OL and the electrode part OLP may be formed on the base layer BSL.

A conductive layer or an insulating layer on the base layer BSL may be formed based on an ordinary process for manufacturing a semiconductor or display device. For example, the conductive layer or the insulating layer on the base layer BSL may be deposited in various manners (sputtering, chemical vapor deposition, and the like) and patterned through a photolithography process. However, the disclosure is not necessarily limited to a specific example.

In this step S100, a pixel circuit PXC may be formed on the base layer BSL, and a repair pixel circuit RPXC may be formed. For example, the pixel circuit PXC may comprise a first pixel circuit PXC1 for a first sub-pixel SPX1, a second pixel circuit PXC2 for a second sub-pixel SPX2, and a third pixel circuit PXC3 for a third sub-pixel SPX3.

In some embodiments, first to third sub-pixels SPX1 to SPX3 may be sequentially disposed along the first direction DR1 to form a first pixel unit PXU1. Other first to third sub-pixels SPX1 to SPX3 may also be sequentially disposed along the first direction DR1 to form a second pixel unit PXU2. The first pixel unit PXU1 and the second pixel unit PXU2 may be adjacent to each other in a direction (e.g., the second direction DR2) different from a direction in which the first to third sub-pixels SPX1 to SPX3 are adjacent to each other.

In this step, the transistors T1 to T7 and DT1 to DT8 described above with reference to FIGS. 7 and 8 and the lines IL, GIL′, ECL, SL, GIL, DL, PL1 electrically connected thereto may be patterned.

For example (FIG. 25), an initialization voltage line IL for supplying an initialization voltage VINIT may be formed by an active layer ACT to extend along the first direction DR1. A second initialization control line GIL′ for supplying a second initialization control signal GB may be formed by a first interlayer conductive layer ICL1 to extend along the first direction DR1. A data line DL for supplying a data signal DATA may be formed by a third interlayer conductive layer ICL3 to extend along the second direction DR2. A first power line PL1 for supplying a first voltage potential VDD may be formed by the third interlayer conductive layer ICL3 to extend along the second direction DR2. In some embodiments, a scan line SL for supplying a scan signal GW, an emission control line ECL for supplying an emission control signal EM, and a first initialization control line GIL for supplying a first initialization signal GI may be patterned to extend along the first direction DR1.

In another example (FIG. 28), the second initialization control line GIL′ for supplying the second initialization control signal GB may be formed by the third interlayer conductive layer ICL3 to extend along the first direction DR1.

The data line DL for supplying the data signal DATA may be formed by a fourth interlayer conductive layer ICL4 to extend along the second direction DR2. The first power line PL1 for supplying the first voltage potential VDD may be formed by the fourth interlayer conductive layer ICL4 to extend along the second direction DR2.

In this step S100, the line part OL and the electrode part OLP may be formed. In some embodiments, the line part OL may be formed by a second interlayer conductive layer ICL2, and the electrode part OLP may be formed by the third interlayer conductive layer ICL3 to be patterned through a same process as first and second transistor electrodes TE1 and TE2. However, as described above, the disclosure is not limited thereto. In some embodiments, a bridge part OBRP may be patterned on the line part OL, and the electrode part OLP may be patterned on the bridge part OBRP.

In this step S100, an organic material removing part 1000 (e.g., the electrode part OLP) may be covered by a via layer VIA. For example, the electrode part OLP may be in contact with the via layer VIA.

In this step S100, the line part OL may have a state in which the line part OL is electrically separated from the repair pixel circuit RPXC. The line part OL may be disposed between the first pixel unit PXU1 and the second pixel unit PXU2 as shown in FIG. 15. In some embodiments, the line part OL may extend in a direction (e.g., the first direction DR1) different from a direction in which the first pixel unit PXU1 and the second pixel unit PXU2 are spaced apart from each other.

In this step S100, the electrode part OLP may be selectively patterned in some areas among areas in which the line part OL is disposed. For example, the line part OL may be disposed between the first pixel unit PXU1 and the second pixel unit PXU2. A portion of the line part OL may overlap with the first pixel circuit PXC1 without overlapping with the second pixel circuit PXC2 and the third pixel circuit PXC3 along the second direction DR2. A portion of the line part OL may overlap with the second pixel circuit PXC2 without overlapping with the first pixel circuit PXC1 and the third pixel circuit PXC3 along the second direction DR2. A portion of the line part OL may overlap with the third pixel circuit PXC3 without overlapping with the first pixel circuit PXC1 and the second pixel circuit PXC2.

In this step S100, the electrode part OLP may be disposed between the first initialization control line GIL and the line part OL. The electrode part OLP may be disposed between the data line DL and the first power line PL1.

In this step S100, the electrode part OLP may be adjacent to a first transistor electrode TE1 (e.g., a source electrode) of the bypass transistor T7 along the first direction DR1.

In this step S100, the first transistor electrode TE1 of the bypass transistor T7 and a first transistor electrode TE1 of the emission control transistor T6 may be adjacent to each other in the second direction DR2 and be connected to each other by a connection electrode COE (see, for example, FIG. 25). The connection electrode COE may be formed by the third interlayer conductive layer ICL3. However, in some embodiments, the connection electrode COE may be formed by the fourth interlayer conductive layer ICL4.

In this step S100, the connection electrode COE may maintain a state in which the connection electrode COE is disposed in a non-connection area NCA (FIG. 9) and overlaps with the line part OL in a plan view. The connection electrode COE may have a state in which the connection electrode COE is electrically separated from the line part OL.

Referring to FIGS. 14, 15, 19, 22, 25, and 28, in the step S200 of manufacturing the light-emitting-element layer, a light-emitting-element layer LEL comprising a light emitting element LD may be formed on the pixel-circuit layer PCL.

In this step S200, pixel circuits PXC may be electrically connected to the light emitting element LD through a contact part CNT penetrating the via layer VIA. The first to third sub-pixels SPX1 to SPX3 may be electrically connected to different light emitting elements LD. In some embodiments, the contact part CNT may electrically connect the connection electrode COE and a first electrode ELT1 to each other.

In this step S200, the first electrode ELT1, a pixel defining layer PDL, and a light emitting part EL may be patterned on the pixel-circuit layer PCL. In some embodiments, the light emitting part EL may be manufactured by sequentially depositing organic materials or through an inkjet printing process.

In this step S200, the electrode part OLP may overlap with the light emitting part EL, the via layer VIA, and the pixel defining layer PDL in a plan view.

In this step S200, the light emitting element LD may not be electrically connected to the line part OL electrically connected to the repair pixel circuit RPXC by the non-connection area NCA. Accordingly, the light emitting element LD may have a state in which the light emitting element LD emits light, based on a driving current supplied from the pixel circuit PXC.

Referring to FIGS. 14, 16, 20, 21, 26, and 29, in the step S300 of performing the organic layer removing process, at least a portion of an organic layer 2000 on an organic layer removing part 1000 may be removed.

In this step S300, a pulse input may be applied to the organic layer removing part 1000, resulting in thermal energy being generated in the electrode part OLP disposed in a relatively narrow area. Accordingly, in accordance with an embodiment of the disclosure, as at least a portion of the organic layer 2000 overlapping with the electrode part OLP on a plane may be removed, an organic material removed area ORA may be formed.

In some embodiments, the organic material removed area ORA may correspond to an area in which the electrode part OLP is disposed. For example, the organic material removed area ORA may be disposed between the first pixel unit PXU1 and the second pixel unit PXU2. The organic material removed area ORA may be formed between pixel circuits PXC adjacent to each other in the second direction DR2.

In this step S300, as at least a portion of the via layer VIA overlapping with the electrode part OLP is removed, the electrode part OLP may be exposed. As a portion of the pixel defining layer PDL overlapping with the electrode part OLP is removed, a first pixel defining layer PDL1 and a second pixel defining layer PDL2, which are spaced apart from each other, may be manufactured. As a portion of the light emitting part EL overlapping with the electrode part OLP is removed, a first light emitting part EL1 and a second light emitting part EL2, which are spaced apart from each other, may be manufactured.

As described above, the first light emitting part EL1 and the second light emitting part EL2 are in different sub-pixels SPX, and hence a risk of a leakage current between the sub-pixels SPX can be reduced by the organic material removing part 1000.

In this step S300, when the electrode part OLP is electrically connected to the line part OL by the bridge part OBRP, the electrode part OLP may be relatively more adjacent to the light-emitting-element layer LEL. Thus, organic materials on the electrode part OLP may be more thoroughly removed.

In some embodiments, a shape of the organic material removed area ORA on a plane may correspond to a shape of the electrode part OLP. For example, the organic material removed area ORA and the electrode part OLP may substantially have a same shape (e.g., a quadrangular shape or the like), and a size of the organic material removed area ORA may be relatively greater than a size of the electrode part OLP.

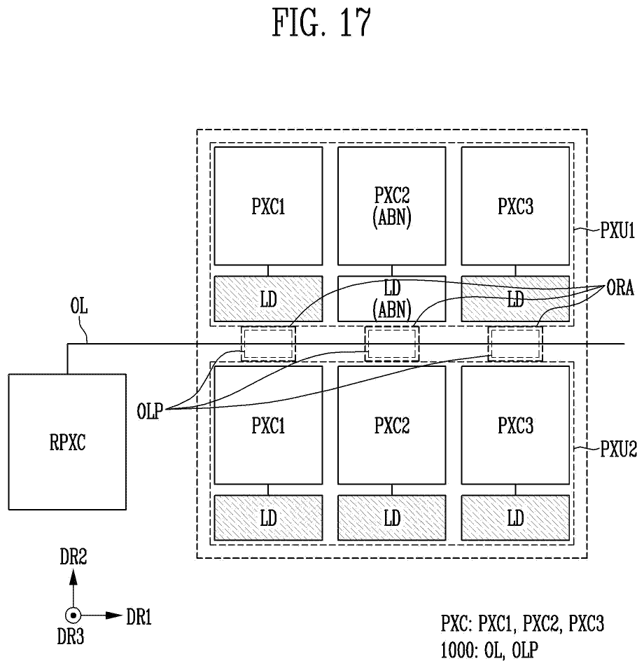

Referring to FIGS. 14 and 17, in the step S400 of inspecting the pixel circuit, it may be decided whether the sub-pixels SPX normally operate. For example, an inspection process may be performed in a manner that checks whether each sub-pixel SPX emits intended light by performing a lighting test on the sub-pixel SPX.

In this step, it may be inspected whether each sub-pixel SPX normally emits light. When the sub-pixel SPX normally emits light, it may be decided that a pixel circuit PXC corresponding to the sub-pixel SPX is normal. When the sub-pixel SPX abnormally operates (ABN), it may be decided that a pixel circuit PXC corresponding to the sub-pixel SPX is defective (or abnormal).

In order to prevent damage of the visibility of the display device DD and improve the display quality of the display device DD, it is necessary to repair a light emitting element LD electrically connected to the pixel circuit PXC which abnormally operates (ABN).

Referring to FIGS. 14, 18, 23, 27, and 30, in the step S500 of performing the repair process, a light emitting element LD decided as a target to be repaired may be electrically connected to the repair pixel circuit RPXC through the line part OL.

In this step S500, the light emitting element LD as the target to be repaired and the pixel circuit PXC which abnormally operates (ABN) may be electrically separated from each other. For example, with respect to an electrical path, a source electrode or a transistor electrode of each of the emission control transistor T6 and the bypass transistor T7, which are electrically adjacent to an anode electrode ANO of the light emitting element, may be cut. For example, at least a portion of one electrode defined at a side different from an output node No of each of the emission control transistor T6 and the bypass transistor T7 may be cut.

In this step, the light emitting element LD as the target to be repaired and the line part OL may be electrically connected to each other. Accordingly, the light emitting element LD as the target to be repaired may be electrically connected to the repair pixel circuit RPXC. For example, the line part OL and the connection electrode COE may be electrically connected to each other in a connection area CA. In some embodiments, an anode connection contact part CCNT for electrically connecting the connection electrode COE and the line part OL to each other may be formed. Consequently, the line part OL can be electrically connected to the anode electrode ANO of the light emitting element LD through the anode connection contact part CCNT, the connection electrode COE, and the contact part CNT.

Accordingly, the light emitting element LD as the target to be repaired is electrically separated from the pixel circuit PXC, which abnormally operates (ABN), and is electrically connected to the repair pixel circuit RPXC, which may normally operate. Thus, the light emitting element LD can be configured to normally emit light. In some embodiments, the repaired light emitting element LD may be designated as a “repaired light emitting element.”

In accordance with the disclosure, there can be provided a display device and a method of manufacturing a display device, in which a risk such as a leakage current can be prevented.

In accordance with the disclosure, there can be provided a display device and a method of manufacturing a display device, in which high-resolution display performance can be improved.

In accordance with the disclosure, there can be provided a display device and a method of manufacturing a display device, in which a process is simplified so that the degree of freedom in a line design can be increased.

Example embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a pixel-circuit layer comprising a pixel circuit and an auxiliary pixel circuit on a base layer; and
a light-emitting-element layer comprising a light emitting element electrically connected to the pixel circuit,
wherein the pixel-circuit layer comprises a line part and an electrode part electrically connected to the line part,
wherein the light-emitting-element layer comprises an organic layer comprising a first region and a second region,
wherein, in a plan view, the first region and the second region are spaced apart from each other with the electrode part interposed therebetween, and wherein the line part is electrically connected to the auxiliary pixel circuit.

2. The display device of claim 1, wherein the light-emitting-element layer further comprises a repaired light emitting element electrically separated from the pixel circuit, the repaired light emitting element being electrically connected to the auxiliary pixel circuit, and
wherein each of the light emitting element and the repaired light emitting element comprises an anode electrode, a cathode electrode, and a light emitting part electrically connected between the anode electrode and the cathode electrode, the light emitting part comprising an organic material.

3. The display device of claim 2, wherein the line part is electrically connected to the repaired light emitting element through a connection area and is not electrically connected to the light emitting element, a non-connection area being interposed between the line part and the light emitting element.

4. The display device of claim 2, wherein the light emitting part comprises a first light emitting part and a second light emitting part, which are spaced apart from each other, and
wherein the first region of the organic layer comprises the first light emitting part, and
the second region of the organic layer comprises the second light emitting part.

5. The display device of claim 4, wherein the light-emitting-element layer further comprises a pixel defining layer comprising a first pixel defining layer and a second defining layer, which define an area in which the light emitting part is disposed and are spaced apart from each other, and
wherein the first region of the organic layer further comprises the first pixel defining layer, and
the second region of the organic layer further comprises the second pixel defining layer.

6. The display device of claim 2, wherein each of the pixel circuit and the auxiliary pixel circuit comprises a driving transistor, a switching transistor, a compensation transistor, an initialization transistor, an operation control transistor, an emission control transistor, and a storage capacitor,
wherein the pixel circuit further comprises a bypass transistor,
wherein the auxiliary pixel circuit further comprises a capacitance control transistor, a capacitive element initialization transistor, and a compensation transistor, and
wherein the line part is electrically connected to an output node between the capacitance control transistor and the capacitive element initialization transistor.

7. The display device of claim 6, wherein the repaired light emitting element is electrically connected to the line part through a connection electrode, and
wherein the connection electrode is electrically separated from the emission control transistor and the bypass transistor of the pixel circuit.

8. The display device of claim 7, wherein the light emitting element is electrically connected to the emission control transistor and the bypass transistor of the pixel circuit through an electrode which is not electrically connected to the line part.

9. The display device of claim 7, wherein the pixel-circuit layer further comprises a data line and a power line, which are electrically connected to the pixel circuit,
wherein the data line and the power line are spaced apart from each other in a first direction, and extend in a second direction different from the first direction, and
wherein the electrode part is disposed between the data line and the power line and is adjacent to the connection electrode along the first direction.

10. The display device of claim 1, wherein the pixel-circuit layer comprises a first interlayer conductive layer, a second interlayer conductive layer on the first interlayer conductive layer, and a third interlayer conductive layer on the second interlayer conductive layer, and
wherein the line part is formed by the second interlayer conductive layer, and
the electrode part is formed by the third interlayer conductive layer.

11. The display device of claim 1, wherein the pixel-circuit layer comprises a first interlayer conductive layer, a second interlayer conductive layer on the first interlayer conductive layer, a third interlayer conductive layer on the second interlayer conductive layer, and a fourth interlayer conductive layer on the third interlayer conductive layer,
wherein the pixel-circuit layer further comprises a bridge part electrically connecting the line part and the electrode part to each other, and
wherein the line part is formed by the second interlayer conductive layer, the bridge part is formed by the third interlayer conductive layer, and the electrode part is formed by the fourth interlayer conductive layer.

12. The display device of claim 1, wherein the first region of the organic layer and the region of the second organic layer are spaced apart from each other with an organic material removed area interposed therebetween, and
wherein the pixel-circuit layer further comprises a via layer directly adjacent to the light-emitting-element layer, and the via layer is not disposed in the organic material removed area.

13. The display device of claim 12, wherein, in a plan view, the electrode part does not overlap with an area in which the anode electrode and the light emitting part are in contact with each other.

14. The display device of claim 1, wherein the light emitting element comprises a plurality of light emitting elements forming sub-pixels which are different from each other and are adjacent to each other along one direction, and
wherein the line part is disposed between the adjacent sub-pixels.

15. A display device comprising:
a sub-pixel and a repaired sub-pixel, formed on a base layer, the sub-pixel and the repaired sub-pixel, each comprising a light emitting element; and
a line part disposed on the base layer and an electrode part on the line part,
wherein the light emitting element of each of the sub-pixel and the repaired sub-pixel comprises a first electrode, a second electrode, and a light emitting layer which is electrically connected between the first electrode and the second electrode and comprises an organic material,
wherein the sub-pixel comprises a pixel circuit,
wherein the repaired sub-pixel comprises a repair pixel circuit,
wherein the line part electrically connects the repair pixel circuit to the light emitting element of the repaired sub-pixel, and
wherein, in a plan view, the light emitting layer comprises a first light emitting layer and a second light emitting layer, which are spaced apart from each other, and the electrode part is disposed between the first light emitting layer and the second light emitting layer.

16. A method of manufacturing a display device, the method comprising:
manufacturing a pixel-circuit layer comprising a pixel circuit, a repair pixel circuit, a line part electrically connected to the repair pixel circuit, and an electrode part electrically connected to the line part;
disposing a light-emitting-element layer comprising light emitting elements on the pixel-circuit layer;
removing at least a portion of an organic layer disposed on the electrode part by applying a pulse input to the line part;
inspecting the pixel circuit; and
performing a repair process of electrically connecting the repair pixel circuit to at least some of the light emitting elements.

17. The method of claim 16, wherein each of the light emitting elements comprises an anode electrode, a cathode electrode, and a light emitting part which is electrically connected between the anode electrode and the cathode electrode, the light emitting part comprising an organic material, and
wherein the removing comprises removing at least a portion of the light emitting part.

18. The method of claim 17, wherein the inspecting comprises deciding whether the light emitting element normally operates, and
wherein, during the inspecting, the light emitting elements are electrically connected to the pixel circuit and are not electrically connected to the repair pixel circuit.

19. The method of claim 18, wherein the performing of the repair process comprises:
electrically separating a light emitting element to be repaired from the pixel circuit, the inspecting identifying the light emitting element to be repaired as one of the light emitting elements and not operating normally; and
electrically connecting the light emitting element to be repaired to the repair pixel circuit.

20. The method of claim 19, wherein the pixel circuit comprises an emission control transistor and a bypass transistor,
wherein the manufacturing the pixel-circuit layer comprises forming a connection part having at least a portion overlapping with the line part in a plan view, the connection part being electrically connected to the anode electrode, and
wherein the performing of the repair process comprises electrically connecting the connection electrode and the line part to each other.
